(19) United States
(12) Patent Application Publication
(10) Pub. No.: US 2021/0265862 A1
(43) Pub. Date: Aug. 26, 2021

(54) ELECTRONIC DEVICE INCLUDING TRANSMISSION STRUCTURE FOR NON-CONTACT WIRELESS POWER TRANSMISSION AND NON-CONTACT DATA COMMUNICATION

(71) Applicant: SAMSUNG ELECTRONICS CO., LTD., Suwon-si (KR)

(72) Inventors: Sungku YEO, Suwon-si (KR); Chongmin LEE, Suwon-si (KR); Jaeseok PARK, Suwon-si (KR); Youngho RYU, Suwon-si (KR); Jeongman LEE, Suwon-si (KR)

(21) Appl. No.: 17/036,940

(22) Filed: Sep. 29, 2020

(30) Foreign Application Priority Data
Feb. 26, 2020 (KR) 10-2020-0023851

(51) Int. Cl. H02J 50/10; H02K 7/14; H05K 5/02; B25J 13/00; B25J 9/12

(52) U.S. Cl. CPC H02J 50/10; H02K 7/14; H01F 1/344; B25J 13/006; B25J 9/12; H05K 5/0217

(57) ABSTRACT

An electronic device and a method of controlling the electronic device are provided. The electronic device includes: a first housing, a second housing configured to detachably and rotatably engage with the first housing upon a first rotation axis, and defining an inner space when engaged with the first housing, a first waveguide supported by the first housing and extending toward the second housing along the first rotation axis in the inner space, a second waveguide supported by the second housing, extending toward the first housing along the first rotation axis in the inner space, and aligned to be spaced apart from the first waveguide by a predetermined distance, a first coil disposed in the first housing and outside the first waveguide, and a second coil disposed in the second housing, outside the second waveguide, and at a position corresponding to the first coil.

### CROSS-REFERENCE TO RELATED APPLICATION

This application is based on and claims priority under 35 U.S.C. § 119 to Korean Patent Application No. 10-2020-0023851, filed on Feb. 26, 2020 in the Korean Intellectual Property Office, the disclosure of which is incorporated by reference herein in its entirety.

### BACKGROUND

### Field

The disclosure relates to an electronic device including a transmission structure for non-contact wireless power transmission and non-contact data communication.

### Description of Related Art

An electronic device refers to a device which executes a specific function according to a loaded program, such as a home appliance, an electronic notebook, a portable multimedia player (PMP), a mobile communication terminal, a tablet personal computer (PC), a video/audio player, a desktop/laptop computer, a vehicle navigation system, or the like. For example, such electronic devices may output stored information as sound or an image.

As the integration level of electronic devices increases and ultra-high-speed, large-capacity wireless communication becomes popular, a single electronic device such as a mobile communication terminal may be equipped with various functions in recent years. For example, an entertainment function such as a game, a multimedia function such as music/video play, a communication and security function for mobile banking, schedule management, an electronic wallet, and so on as well as a communication function are integrated in one electronic device. These electronic devices are being miniaturized so that users carry them conveniently.

A robot (or robot system) is the result of integration of one or more high-tech electronic devices. Electronic devices incorporated in one robot obtain information about the surroundings of the robot or information through an internal/external communication network, represent analyzed data, and perform various operations.

Power supply to each electronic device in the robot is significant. It is also significant to control power for each function and each operation and maintain an optimal efficiency, beyond simple power supply.

A robot user should be able to monitor and control power consumption according to robot operation scenario-based use/non-use/standby by detecting an operating point offering an optimal efficiency through power analysis for each function.

Further, a module or an accessory may be added to the interior or exterior of the robot, for function extension and application modification in the robot.

To perform various operations using the robot, the robot may be subjected to function extension and application modification. The function extension and the application modification may be realized by attaching an additional module or accessory to the interior or exterior of a robot body.

When an additional module or accessory is attached to the robot body, high-speed data communication may be required. Conventionally, high-speed data communication is conducted through a moving power line (e.g., cable) connecting the robot body to the additional module or accessory. In this case, the structural/electromagnetic interference of the power line may result in a limited movement range (or rotation radius), low durability, and a limited rotation speed and power amount caused by friction and joints. Moreover, when an external module is added to the robot body, the hardware of the robot body or the design of a power supply may need design modification.

Power and data should be provided to the additional module or accessory attached to the robot body. In this context, a common power module platform is required to efficiently supply power and data to the added module and efficiently manage power even though various functions are added to meet consumers' demands.

### SUMMARY

Embodiments of the disclosure provide an electronic device (e.g., robot) which transmits required power and data to an added module or accessory, based on a non-contact cable-less joint structure.

Embodiments of the disclosure provide an electronic device (e.g., robot) which connects required power and data to an added module or accessory in a non-contact manner and supplies power through a common power module (e.g., power management unit (PMU)).

Additional aspects will be set forth in part in the description which follows and, in part, will be apparent from the description.

According to an example embodiment of the disclosure, an electronic device includes: a first housing, a second housing configured to detachably and rotatably engage with the first housing upon a first rotation axis, and defining an inner space when engaged with the first housing, a first waveguide supported by the first housing and extending toward the second housing along the first rotation axis in the inner space, a second waveguide supported by the second housing extending toward the first housing along the first rotation axis in the inner space, and aligned to be distanced from the first waveguide by a predetermined distance, a first coil disposed in the first housing and outside the first waveguide, and a second coil disposed in the second housing outside the second waveguide and at a position corresponding to the first coil.

According to another example embodiment of the disclosure, an electronic device configured to rotatably engage with an adjacent electronic device including a first waveguide and a first coil disposed outside the first waveguide includes: a second waveguide aligned to be distanced from the first waveguide by a predetermined distance based on the electronic device being engaged with the adjacent electronic device, a second coil disposed outside the second waveguide, the second coil disposed at a position corresponding to the first coil when the electronic device is engaged with the adjacent electronic device, and a rotation means (ex., motor) configured to rotate the electronic device upon a rotation axis with respect to the adjacent electronic device.

According to another example embodiment of the disclosure, a method of operating an electronic device includes: detecting an external device in response to engagement with the external device, transmitting first power to operate a processor of the external device through a first coil, receiving information about the external device from the external device based on the operation of the processor of the external device, determining a power-related parameter for power to be transmitted to the external device based on the information received from the external device, transmitting second power through the first coil based on the determined power-related parameter, and transmitting and receiving data to and from a second waveguide of the external device through a first waveguide.

### BRIEF DESCRIPTION OF THE DRAWINGS

The above and other aspects, features, and advantages of certain embodiments of the present disclosure will be more apparent from the following detailed description, taken in conjunction with the accompanying drawings, in which:

FIG. 1 is a diagram illustrating example connections between an electronic device included in a robot and devices according to an embodiment of the disclosure;

FIG. 2 is a block diagram illustrating example components of electronic devices according to an embodiment of the disclosure;

FIG. 3 is a diagram illustrating an example non-contact connection structure between an electronic device and a device according to various embodiments of the disclosure;

FIG. 4 is a diagram illustrating an example non-contact connection structure between an electronic device and a device according to various embodiments of the disclosure;

FIG. 5 is a diagram illustrating an example coil added to the non-contact connection structure between an electronic device and a device, illustrated in FIG. 3 according to various embodiments of the disclosure;

FIG. 6A is a cross-sectional perspective view illustrating a first waveguide and a second waveguide according to an embodiment of the disclosure;

FIG. 6B is a cross-sectional view illustrating a first waveguide and a second waveguide according to an embodiment of the disclosure;

FIG. 6C is a graph illustrating example frequency characteristics of the embodiment illustrated in FIG. 6B according to an embodiment of the disclosure;

FIG. 7A is a cross-sectional perspective view illustrating a first waveguide and a second waveguide according to an embodiment of the disclosure;

FIG. 7B is a cross-sectional view illustrating a first waveguide and a second waveguide according to an embodiment of the disclosure;

FIG. 7C is a graph illustrating example frequency characteristics of the embodiment illustrated in FIG. 7B according to an embodiment of the disclosure;

FIG. 7D is a cross-sectional view illustrating a cross section of a first waveguide and a second waveguide according to an embodiment of the disclosure;

FIG. 7E is a graph illustrating example frequency characteristics of the embodiment illustrated in FIG. 7D according to an embodiment of the disclosure;

FIG. 7F is a cross-sectional view illustrating a first waveguide and a second waveguide according to an embodiment of the disclosure;

FIG. 8A is a diagram illustrating example recesses formed in a first waveguide and a second waveguide according to an embodiment of the disclosure;

FIG. 8B is a diagram illustrating example recesses formed in a first waveguide and a second waveguide according to an embodiment of the disclosure;

FIG. 8C is a diagram illustrating example recesses formed in a first waveguide and a second waveguide according to an embodiment of the disclosure;

FIG. 8D is a diagram illustrating example recesses formed in a first waveguide and a second waveguide according to an embodiment of the disclosure;

FIG. 9 is a diagram illustrating an example non-contact connection structure between an electronic device and a device according to various embodiments of the disclosure;

FIG. 10 is a diagram illustrating an example non-contact connection structure between an electronic device and a device according to an embodiment of the disclosure;

FIG. 11 is a sectional view illustrating the non-contact connection structure between an electronic device and a device, taken along line A-A′ illustrated in FIG. 10 according to an embodiment of the disclosure;

FIG. 12 is a perspective view illustrating example engagement between a first electronic device and a second electronic device illustrated in FIG. 10 according to an embodiment of the disclosure;

FIG. 13 is an exploded perspective view illustrating an example of a hollow motor according to various embodiments of the disclosure;

FIG. 14 is a signal flow diagram illustrating an example operation between electronic devices according to an embodiment of the disclosure;

FIG. 15 is a block diagram illustrating an example electronic device according to various embodiments;

FIG. 16 is a block diagram illustrating an example electronic device according to various embodiments;

FIG. 17 is a block diagram illustrating an example electronic device according to various embodiments;

FIG. 18 is a block diagram illustrating an example power management unit (PMU) according to various embodiments;

FIG. 19A is a diagram illustrating example connection relationships of a robot body according to various embodiments;

FIG. 19B is a diagram illustrating example connection relationships of a robot head according to various embodiments;

FIG. 20A is a cross-sectional view illustrating a first waveguide and a second waveguide in which first recesses are formed according to an embodiment of the disclosure;

FIG. 20B is a cross-sectional view illustrating a first waveguide and a second waveguide in which first recesses are formed according to an embodiment of the disclosure;

FIG. 20C is a side view illustrating cross sections of a first waveguide and a second waveguide in which first recesses are formed according to an embodiment of the disclosure;

FIG. 20D is a cross-sectional view illustrating a first waveguide and a second waveguide in which first recesses are formed according to an embodiment of the disclosure;

FIG. 20E is a cross-sectional view illustrating a first waveguide and a second waveguide in which first recesses are formed according to an embodiment of the disclosure;

FIG. 21A is a cross-sectional view illustrating a first waveguide and a second waveguide in which first recesses and second recesses are formed according to an embodiment of the disclosure;

FIG. 21B is a cross-sectional view illustrating a first waveguide and a second waveguide in which first recesses and second recesses are formed according to an embodiment of the disclosure;

FIG. 21C is a cross-sectional view illustrating a first waveguide and a second waveguide in which first recesses and second recesses are formed according to an embodiment of the disclosure;

FIG. 21D is a cross-sectional view illustrating a first waveguide and a second waveguide in which first recesses and second recesses are formed according to an embodiment of the disclosure;

FIG. 21E is a cross-sectional view illustrating a first waveguide and a second waveguide in which first recesses and second recesses are formed according to an embodiment of the disclosure;

FIG. 22A is a cross-sectional view illustrating a first waveguide and a second waveguide in which first recesses and third recesses are formed according to an embodiment of the disclosure;

FIG. 22B is a cross-sectional view illustrating a first waveguide and a second waveguide in which first recesses and third recesses are formed according to an embodiment of the disclosure;

FIG. 22C is a cross-sectional view illustrating a first waveguide and a second waveguide in which first recesses and third recesses are formed according to an embodiment of the disclosure;

FIG. 22D is a cross-sectional view illustrating a first waveguide and a second waveguide in which first recesses and third recesses are formed according to an embodiment of the disclosure;

FIG. 22E is a cross-sectional view illustrating a first waveguide and a second waveguide in which first recesses and third recesses are formed according to an embodiment of the disclosure;

FIG. 23A is a cross-sectional view illustrating cross sections of a first waveguide and a second waveguide in which fourth recesses and fifth recesses are formed according to an embodiment of the disclosure;

FIG. 23B is a cross-sectional view illustrating cross sections of a first waveguide and a second waveguide in which fourth recesses and fifth recesses are formed according to an embodiment of the disclosure;

FIG. 23C is a cross-sectional view illustrating cross sections of a first waveguide and a second waveguide in which fourth recesses and fifth recesses are formed according to an embodiment of the disclosure;

FIG. 23D is a cross-sectional view illustrating cross sections of a first waveguide and a second waveguide in which fourth recesses and fifth recesses are formed according to an embodiment of the disclosure;

FIG. 23E is a cross-sectional view illustrating cross sections of a first waveguide and a second waveguide in which fourth recesses and fifth recesses are formed according to an embodiment of the disclosure; and

FIG. 24 is a block diagram illustrating an example electronic device in a network environment according to various embodiments.

### DETAILED DESCRIPTION

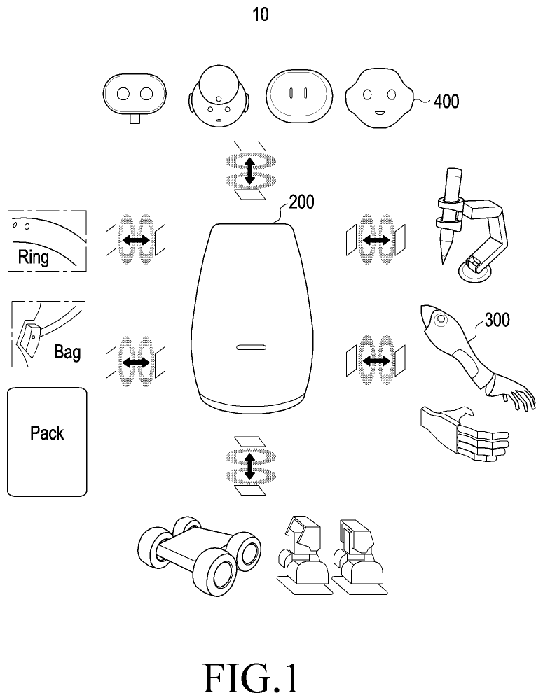

FIG. 1 is a diagram illustrating example connections between an electronic device 200 (e.g., the first electronic device or the body unit) included in a robot 10 and devices 300 and 400 (e.g., the second electronic devices or the application units) according to an embodiment of the disclosure.

According to various embodiments of the disclosure, the robot 10 may be an electronic device capable of autonomously moving, deciding, and/or operating. Examples of the robot 10 may include, without limitation, a wireless cleaning robot, an unmanned robot, an autonomous driving vehicle, an unmanned aerial vehicle (e.g., a drone), or the like. Besides, as far as it is capable of making an autonomous action or movement, anything may be encompassed as the robot 10 mentioned herein. While the robot 10 is taken as an example in the following embodiments, various embodiments of the disclosure are applicable to any electronic device in which first and second electronic devices are engaged and communicate with each other.

The electronic device 200 illustrated in FIG. 1 may be a part of the robot 10. According to various embodiments of the disclosure, the robot 10 may move under remote control of a user as well as autonomously behave without a user command. According to various embodiments of the disclosure, the electronic device 200 may be loaded with artificial intelligence (AI), so that the robot 10 may operate by learning (machine learning or deep learning).

Referring to FIG. 1, the electronic device 200 according to various embodiments of the disclosure may be used in connection to the plurality of devices 300 and 400 (e.g., the second electronic devices or application units). As the plurality of devices 300 and 400 are connected to the electronic device 200, the functions of the electronic device 200 may be extended.

The plurality of devices 300 and 400 may be modules or accessories attachable to the interior or exterior of the robot 10, additionally or alternatively to other components of the electronic device 200, for the purpose of function extension and/or application modification in the robot 10. The plurality of devices 300 and 400 may be separate electronic devices distinguished from the electronic device 200. According to an embodiment, the plurality of devices 300 and 400 may execute or invoke functions independently of the electronic device 200. While the plurality of devices 300 and 400 are shown in FIG. 1 as configured separately from the electronic device 200, the plurality of devices 300 and 400 may be combined with the electronic device 200 into one electronic device (e.g., a united whole robot).

For example, the electronic device 200 (the first electronic device) may correspond to a body unit of the robot 10. Each of the plurality of devices 300 and 400 (the second electronic devices) as application units detachably engaged with the body of the robot 10 may be a robot head, a robot arm, a robot hand, a robot driver, any other accessory, a manipulator, or a display. Other components executing various functions may also be available as the plurality of electronic devices 300 and 400. For example, the robot driver may be a component to which various movement apparatus and/or circuitry are applied. Various movement apparatus and/or circuitry may conceptually encompass movement means such as a driving means, a flying means, and so on. As far as it is used to change the position of the electronic device 200, anything may be included in various movement means of the disclosure.

According to various embodiments, at least one of the plurality of electronic devices 300 and 400 may be engaged with the electronic device 200 directly or indirectly through another device. For example, one device may be detachably engaged with another device. For example, the display may be engaged with the robot head. In this case, the display may be engaged with the electronic device 200 (e.g., the body unit) indirectly through the robot head.

As described above, engagements or connections between the electronic device 200 and the plurality of devices 300 and 400 may include physical and electrical connections, and direct or indirect connections between different components. The engagements or connections between the electronic device 200 and the plurality of devices 300 and 400 may include a partial engagement or connection via fastening means (e.g., a bolt and a nut).

Further, the engagements or connections between the electronic device 200 and the plurality of devices 300 and 400 may include network connections. A network connection may refer, for example, to a state in which data is transmittable and/or receivable or resources are sharable between two devices. That is, the network connection may refer to a state in which two devices are connected to a network by wired/wireless communication. For this purpose, the two devices may be connected to the network by direct communication (device-to-device (D2D) communication) or indirect communication via another device (e.g., an access point (AP), a router, or the like).

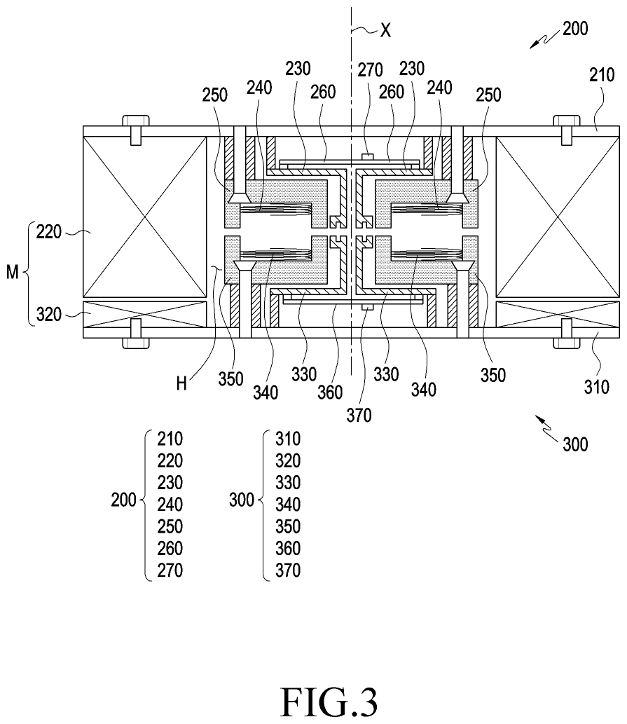

Further, the engagements or connections between the electronic device 200 and the plurality of devices 300 and 400 may include a “non-contact connection”. The non-contact connection may refer, for example, to execution of a specific function (e.g., data and/or power transmission) between the electronic device 200 and the plurality of devices 300 and 400 by physically spaced connection structures for the function. However, it is to be noted that configuration of a non-contact connection structure for executing a specific function between the electronic device 200 and the plurality of devices 300 and 400 does not necessarily limit any other connection structure between the electronic device 200 and the plurality of devices 300 and 400. For example, when a non-contact connection structure is constructed for data and/or power transmission between the electronic device 200 and the plurality of devices 300 and 400, other parts (e.g., housings) may be directly engaged or fastened with each other between the electronic device 200 and the plurality of devices 300 and 400, so that the electronic device 200 and the plurality of devices 300 and 400 may not be disconnected from each other during operation. An example non-contact connection structure between the electronic device 200 and the plurality of devices 300 and 400 will be described in greater detail below with reference to FIG. 3.

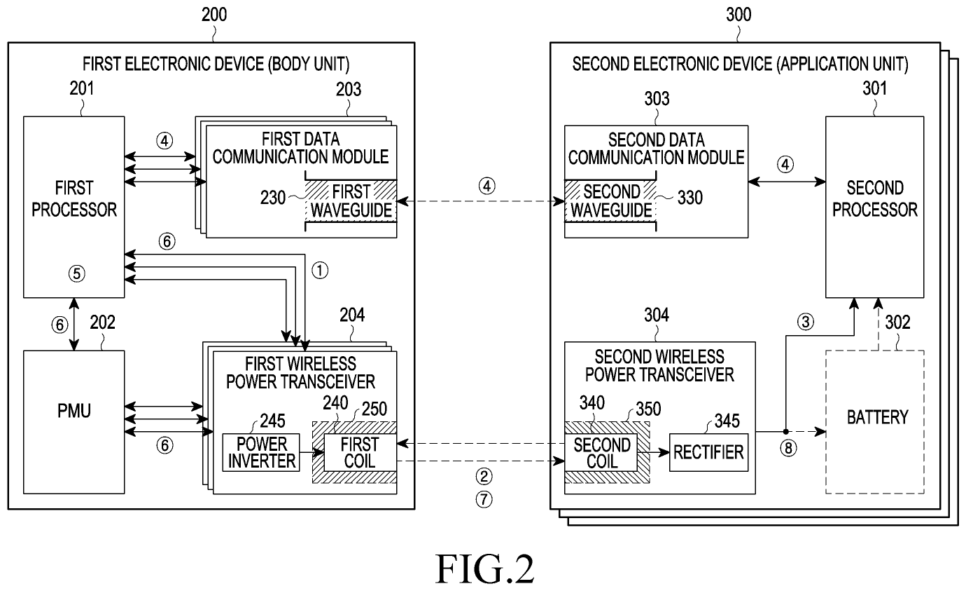

FIG. 2 is a block diagram illustrating example components of electronic devices (the first electronic device 200 and second electronic devices 300) according to an embodiment of the disclosure. Referring to FIG. 2, the first electronic device 200 (the body unit) of the robot 10 may operate in engagement with at least one second electronic device 300 (an application unit). FIG. 2 illustrates an example in which one first electronic device 200 operates in engagement with a plurality of second electronic devices 300.

With the first electronic device 200 engaged with each of the second electronic devices 300, the second electronic device 300 may rotate with respect to the first electronic device 200. According to various embodiments, the first electronic device 200 may include a first processor (e.g., including processing circuitry) 201, a power management unit (PMU) (e.g., including power management circuitry) 202, at least one first data communication module (e.g., including communication circuitry) 203, and at least one first wireless power transceiver (e.g., including power transceiving circuitry) 204. According to various embodiments, each of the second electronic devices 300 may include a second processor (e.g., including processing circuitry) 301, a battery 302, a second data communication module (e.g., including communication circuitry) 303, and a second wireless power transceiver (e.g., including power transceiving circuitry) 304.

While not shown in FIG. 2, the second electronic device 300 may further include a PMU.

According to various embodiments, for example, the first processor 201 or the second processor 301 may include various processing circuitry and control at least one other component (e.g., a hardware or software component) of the electronic device 200 or 300 connected to the first processor 201 or the second processor 301 by executing software, and perform various data processes and computations. For example, the first processor 201 may control other components including the PMU 202, the first data communication modules 203, and the first wireless power transceivers 204, and process data received from the PMU 202, the first data communication modules 203, and the first wireless power transceivers 204. The second processor 201 may control other components including the second data communication module 303 and the second wireless power transceiver 304, and process data received from the second data communication module 303 and the second wireless power transceiver 304.

Each of the first data communication modules 203 may include various communication circuitry and execute a function of converting data received from the first processor 201 to a signal in a format transmittable to an external device. For example, the first data communication module 203 may include a modulator, a digital-to-analog (D/A) converter, and a radio frequency integrated circuit (RF IC), and convert digital data received from the first processor 201 to a high-frequency wireless data signal (e.g., millimeter wave (mmWAVE) signal). According to various embodiments, the first data communication module 203 may include a first waveguide 230, and the high-frequency wireless data signal generated from the first data communication module 203 may be transmitted through the first waveguide 230 to a second waveguide 330 included in the second data communication module 303 of the second electronic device 300. As the first electronic device 200 is engaged with the second electronic device 300, the first waveguide 230 of the first electronic device 200 and the second waveguide 330 of the second electronic device 300 may be disposed apart from each other by a predetermined distance. A specific arrangement relationship between the first waveguide 230 and the second waveguide 330 will be described in greater detail below with reference to FIG. 3.

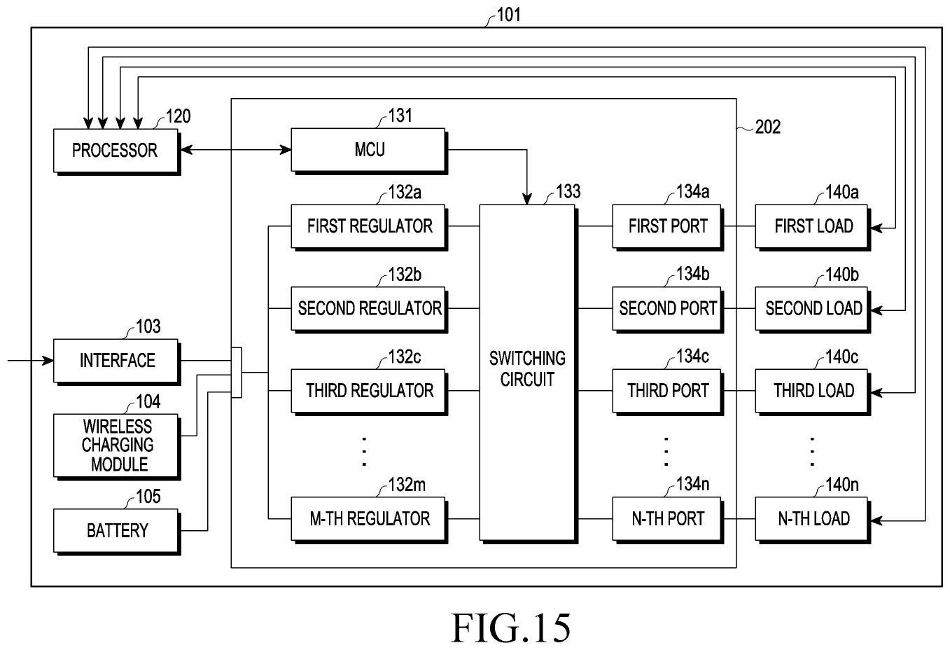

According to various embodiments, the PMU 202 may include various power management circuitry and control power output from each of a plurality of wireless power transceivers 204 under the control of the first processor 201. For example, the PMU 202 may control at least one of the magnitude of a current and/or the magnitude of a voltage in the power from each of the first wireless power transceivers 204 under the control of the first processor 201. The PMU 202 may control or manage power supplied to each of the plurality of second electronic devices 300 engaged with the electronic device 200, and control or manage power supplied to each module or circuit (e.g., the first processor 201, the first data communication modules 203, and the first wireless power transceivers 204) of the first electronic device 200. For convenience of description, an embodiment of supplying power from one of the plurality of first wireless power transceivers 204 to one second electronic device 300 will be described below. A specific embodiment of managing power supplied to the inside of the first electronic device 200 (e.g., a module or circuit inside the first electronic device 200) or the outside of the first electronic device 200 (e.g., the plurality of second electronic devices 300) will be described in greater detail below with reference to FIGS. 15, 16, 17 and 18 (which may be referred to hereinafter as FIGS. 15 to 18 for convenience).

According to various embodiments of the disclosure, each of the first wireless power transceivers 204 may include a power inverter 245 and a first coil 240. The power inverter 245 may receive direct current (DC) power from the PMU 202, and convert the DC power to alternating current (AC) power of a predetermined magnitude according to a power control signal from the first processor 202. The first coil 240 may transmit wireless power to an intended electronic device (e.g., a second electronic device 300) to be charged by transmitting or outputting the AC power converted through the power inverter 245 to a wireless space. The power inverter 245 may be configured to include at least one transistor (e.g., a field effect transistor (FET)), a half bridge circuit, or a full bridge circuit. While only components for wireless power transmission in the first wireless power transceiver 204 are shown in FIG. 2, the first wireless power transceiver 204 may further include a rectifier and thus may further execute a function of rectifying wireless power received through the first coil 240. A detailed implementation example of the first wireless power transceiver 204 will be described with reference to FIG. 3.

According to various embodiments, the first wireless power transceiver 204 may include various power transceiving circuitry and may include a first ferrite core 250 surrounding at least a part of the first coil 240, and the second wireless power transceiver 304 may include various power transceiving circuitry and may include a second ferrite core 350 surrounding at least a part of the second coil 340. For example, the first ferrite core 250 or the second ferrite core 350 may be implemented in the form of a pot ferrite in which the first coil 240 or the second coil 340 may be mounted. As the first electronic device 200 and the second electronic device 300 include the first ferrite core 250 and the second ferrite core 350, respectively, power transmission efficiency may be increased, and leakage of a magnetic field generated between the first coil 240 and the second coil 340 may be prevented and/or reduced. Therefore, the decrease of the efficiency of data transmission/reception through the first waveguide 230 and the second waveguide 330 may be prevented and/or reduced. A specific embodiment of arrangement relationships among the first waveguide 230, the second waveguide 330, the first coil 240, the second coil 340, the first ferrite core 250, and the second ferrite core 350 will be described in greater detail below with reference to FIG. 3.

According to various embodiments, the second wireless power transceiver 340 may receive power from the first coil 240 of the first electronic device 200 through the second coil 340. The AC power received through the second coil 340 may be rectified to DC power in a rectifier 345 and then supplied to the second processor 301 and/or the battery 302. According to various embodiments, when the second electronic device 300 includes a PMU, the DC power rectified by the rectifier 345 may be supplied to the PMU, and the PMU may supply the received DC power to each module or circuit (e.g., the second processor 301) of the second electronic device 300 or other loads.

While components for wireless power reception in the second wireless power transceiver 304 are shown in FIG. 2, the second wireless power transceiver 304 may further execute a function of converting DC power to an AC signal through a power inverter and then transmitting the power converted to the AC signal to a wireless space through the second coil 340 according to various embodiments.

According to various embodiments, a procedure of performing data communication between the first electronic device 200 and the second electronic device 300 which are engaged with each other will be described in greater detail below. When the second electronic device 300 is engaged with the first electronic device 200, the first processor 201 of the first electronic device 200 may detect the second electronic device 300. The first processor 201 of the first electronic device 200 may detect the second electronic device 300 in various manners. For example, the first electronic device 200 may sense engagement with the second electronic device 300 by a sensor (e.g., a hall sensor) included in the first electronic device 200, and transmit the sensed signal to the first processor 201, thereby detecting the engagement with the second electronic device 300.

In another embodiment, as the first coil 240 and the second coil 340 approach each other, the first electronic device 200 may sense a load change by identifying a change in a signal transmitted from the first wireless power transceiver 204. For example, the first wireless power transceiver 204 may sense a load change from a signal transmitted through the first coil 240 and transmit the sensing result to the first processor 201. The first processor 201 may receive the load change sensing result from the first wireless power transceiver 204, and identify that the specific second electronic device 300 has been engaged with a part (e.g., an arm or the head of the robot) corresponding to the first wireless power transceiver 204 in which the load change has been sensed (\textcircled{1}).

According to another embodiment, the first electronic device 200 may identify the second electronic device 300 by short-range wireless communication (e.g., Bluetooth communication or near field communication (NFC)), and transmit wireless power to the second electronic device 300 based on information received from the second electronic device 300 as a result of the identification.

According to various embodiments, the first processor 201 may control transmission of predetermined power (e.g., first power) to the engaged second electronic device 300 through the first wireless power transceiver 204 (\textcircled{2}). According to various embodiments, the predetermined power may be a signal (e.g., a ping or a beacon signal) complying with any of various wireless charging schemes (e.g., a scheme defined in the wireless power consortium (WPC) standard (or Qi standard) or a scheme defined in the alliance for wireless power (A4WP) standard (or air fuel alliance (AFA) standard)). The predetermined power transmitted through the first wireless power transceiver 204 may be power of a predetermined magnitude to operate the second processor 301 of the second electronic device 300. The second wireless power transceiver 304 may receive the power from the first coil 240 of the first wireless power transceiver 204 through the second coil 340. The second wireless power transceiver 304 may convert the AC power received through the second coil 340 to DC power through the rectifier 345. The received power converted to the DC power by the rectifier 345 may be transmitted to the second processor 301 and/or the battery 302 (\textcircled{3}). According to various embodiments, when the second electronic device 300 includes a PMU, the DC power rectified by the rectifier 345 may be supplied to the PMU, and the PMU may supply the received DC power to the second processor 301 and/or the battery 302.

According to various embodiments, the second processor 301 may be operated by the power received through the second wireless power transceiver 304. For example, when the battery 302 of the second electronic device 300 is discharged (e.g., in a dead battery state) and thus the second processor 301 is off, the second processor 301 may wake up by the power received through the second wireless power transceiver 304 and operate normally.

According to various embodiments, as the second processor 301 operates, the second processor 301 may transmit data to the first electronic device 200 through the second data communication module 303 (\textcircled{4}). The data transmitted from the second processor 301 may include information related to the second electronic device 300 (e.g., the identifier (ID) of the second electronic device 300, the type of the second electronic device 300, information about required power of the second electronic device 300, information about a voltage or current related to charging power of the second electronic device 300, and rating information (e.g., an effective value) about the second electronic device 300). According to various embodiments, the first processor 201 of the first electronic device 200 may receive the data from the second electronic device 300 through the first data communication module 203.

The first processor 201 of the first electronic device 200 may determine parameters related to power to be transmitted to the second electronic device 300 (e.g., the voltage or current of the power to be transmitted to the electronic device (e.g., the second electronic device 300) identified as engaged with the first electronic device 200) by a predetermined algorithm (\textcircled{5}). According to various embodiments, when the multiple second electronic devices 300 and 400 are engaged with the first electronic device 300 and the plurality of first wireless power transceivers 204 of the first electronic device 200 transmit power simultaneously to the second electronic devices 300 and 400, the PMU 202 may apply a predetermined algorithm having an optimal charging efficiency based on data received from the second electronic devices 300 and 400 (\textcircled{6}). Various embodiments of determining parameters related to power to be transmitted to the second electronic device 300 by the PMU 202 will be described in greater detail below with reference to FIGS. 15 to 18.

According to various embodiments, the first wireless power transceiver 204 may generate power (e.g., second power) according to the parameters related to the power, determined by the first processor 201 and transmit the generated power to the wireless space through the first coil 240 (\textcircled{7}). The second wireless power transceiver 304 may receive the second power from the first coil 240 of the first wireless power transceiver 204 through the second coil 340. The second wireless power transceiver 304 may receive AC power through the second coil 340 and convert the AC power to a DC signal through the rectifier 345. The power converted to the DC signal by the rectifier 345 may be transmitted to and charge the battery 302 or supplied to the second processor 301 (\textcircled{8}). As described before, when the second electronic device 300 includes a PMU, the power converted to the DC signal by the rectifier 345 may be supplied to the battery 301, the second processor 301, or each circuit of the second electronic device 300 through the PMU.

According to various embodiments, the second processor 301 of the second electronic device 300 may perform a specific operation by the power received from the first electronic device 200. For example, the second electronic device 300 may transmit data to and receive data from the first electronic device 200 through the second data communication module 303 (e.g., the second waveguide 330).

FIG. 3 is a diagram illustrating an example non-contact connection structure between the electronic device 200 and the device 300 according to various embodiments of the disclosure. In FIG. 3, a non-contact connection structure between hardware components of the electronic device 200 and the device 300 is shown. In the following description, the electronic device 200 may be referred to as “the first electronic device 200” as in the description of FIG. 2, and the device 300 may be referred to as “the second electronic device 300” as in the description of FIG. 2.

The first electronic device 200 may include a plurality of components for transmission/reception of data and/or power, and the plurality of components may be configured as modules. Likewise, the second electronic device 300 may include a plurality of components for transmission/reception of data and/or power, and the plurality of components may be configured as modules. A module may be an integrally configured part, or a minimum unit or portion of the part, which executes one or more functions.

According to an embodiment, the plurality of components for data and/or power transmission/reception may include a first module and a second module, and the modules may be installed in the first electronic device 200 and the second electronic device 300, respectively. According to various embodiments of the disclosure, the non-contact connection structure between the first electronic device 200 and the second electronic device 300 may refer to a non-contact connection structure between the first module and the second module.

According to various embodiments of the disclosure, the non-contact connection structure may include a first housing 210, the first waveguide 230, the first coil 240, a second housing 310, the second waveguide 330, and the second coil 340.

Referring to FIG. 3, according to an embodiment, the first electronic device 200 may include the first housing 210, a stator 220, the first waveguide 230, the first coil 240, and the ferrite core 250. The second electronic device 300 may include the second housing 310, a rotor 320, the second waveguide 330, the second coil 340, and the second ferrite core 350. According to various embodiments, some of the above components may be omitted or replaced with other components, or one or more other components may be added, in the first electronic device 200 or the second electronic device 300.

The first housing 210 may be configured to support the stator 220, the first waveguide 230, and the first coil 240. The first housing 210 may provide an area (or space) in which the stator 220, the first waveguide 230, and the first coil 240 are arranged at appropriate positions inside the first electronic device 200. The housing 210 is not limited to any particular shape. According to an embodiment, the first housing 210 may provide a space for accommodating components such as the stator 220, the first waveguide 230, and the first coil 240 therein. The first housing 210 may be in a simple, at least partially flat structure. The first housing 210 may be in a “cover” structure to protect the components against external physical, chemical, and electrical shocks. The second housing 310 may be configured to support the rotor 320, the second waveguide 330, and the second coil 340. The second housing 310 may be similar to the first housing 210 in structure and function. A redundant description of the second housing 310 with the description of the first housing 210 is avoided herein.

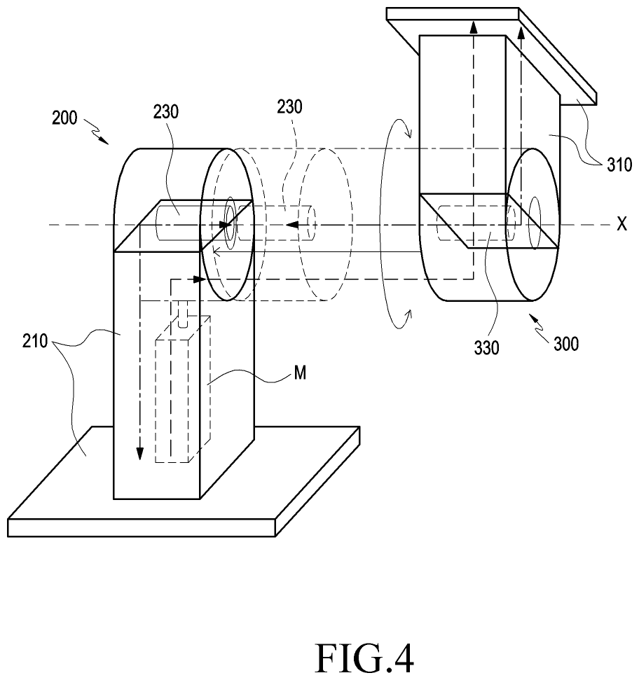

While not shown, the first housing 210 and the second housing 310 may be formed to be detachably engaged with each other. For example, when the functions of the second electronic device 300 are to be added to the robot 10 including the first electronic device 200 as the body unit, a user may simply engage the second housing 310 of the second electronic device 300 with the first housing 210 of the first electronic device 200, thus adding the intended functions. Components that engage the first housing 210 and the second housing 310 with each other may include at least one ball bearing. A detailed description of other connection portions (or fastening portions) will be given later with reference to FIGS. 4 to 13.

According to various embodiments of the disclosure, the robot 10 may include a rotation means (e.g., motor) that rotates the second housing 310 with respect to the first housing 210, as a component of the first electronic device 200 and/or the second electronic device 300. The rotation means may be configured in various types. For example, the first housing 210 and the second housing 310 may be combined into one rotation means (e.g., a motor M). A power source may be connected to one of the first housing 210 or the second housing 310, and the other housing may be engaged with the housing connected to the power source, so that the first housing 210 and the second housing 310 may move integrally. Various other embodiments may also be applied.

Referring to FIG. 3, an embodiment of applying the motor M as a component included in the first electronic device 200 and the second electronic device 300 is illustrated. According to an embodiment, the stator 220 may be a component disposed at one side of the first housing 210, which is stationary or does not move, while generating an electromagnetic field by a field magnet (e.g., a magnet). The rotor 320 may be a component disposed at one side of the second housing 310, apart from the stator 220, and rotate under the action of the electromagnetic field generated from the stator 220. A rotation operation of a joint or manipulator of the robot 10 may be performed for a mutual action between the stator 220 and the rotor 320. That is, the stator 220 and the rotor 320 may form the motor M. According to an embodiment, the first housing 210 engaged with the stator 220 may be kept stationary, while the second housing 310 engaged with the rotor 320 may rotate upon a first rotation axis X with respect to the first housing 210. As described in greater detail below, because the robot 10 according to various embodiments of the disclosure uses a non-contact connection structure, thus without a cable (or wire) for data or power transmission/reception, the second housing 310 may advantageously rotate at 360 degrees upon the first rotation axis X with respect to the first housing 210, without any limitation on a rotation radius. As described later with reference to FIGS. 4 to 13, a specific configuration for rotating the second housing 310 with respect to the first housing 210 is not limited to the above-described embodiment.

According to the embodiment illustrated in FIG. 3, the motor M including the stator 220 and the rotor 320 may be a motor (hollow motor) in which a hollow portion H is formed. As far as the stator 220 and the rotor 320 are spaced from each other, their specific arrangement is not limited to any particular embodiment. In FIG. 3, the hollow portion H is formed, with the stator 220 and the rotor 320 arranged in parallel in a height direction (e.g., a direction in which the second housing 310 is viewed from the first housing 210), which should not be construed as limiting. Instead, the hollow portion may be formed, with the rotor 320 disposed inside the stator 220.

According to various embodiments of the disclosure, the first waveguide 230 and the second waveguide 330 may be arranged in the hollow portion H defined by the stator 220 and/or the rotor 320.

A waveguide may refer, for example, to a kind of pipe including a transmission path (or waveguide path) in which electrical energy or a signal is transmitted. The waveguide may be formed into a pipe being a conductor surrounding the transmission path of electromagnetic waves. The waveguide may have a cross section in any of various shapes including circle, oval, or square, and may be formed of any of various materials such as copper, gold, and silver. The cross section of the waveguide may have various diameters according to the frequencies of electromagnetic waves passing through the waveguide.

According to various embodiments of the disclosure, data may be transmitted/received between the first electronic device 200 and the second electronic device 300 through the waveguides. According to various embodiments of the disclosure, electromagnetic waves may pass through the first waveguide 230 connected to the first electronic device 200 and the second waveguide 330 connected to the second electronic device 300, and signals may be transmitted/received between the first electronic device 200 and the second electronic device 300 by the electromagnetic waves. In the disclosure, as the first waveguide 230 and the second waveguide 330 have a non-contact connection structure, the first waveguide 230 and the second waveguide 330 may be designed to enable high-speed/large-capacity data communication without decreasing a data transmission/reception speed and/or efficiency.

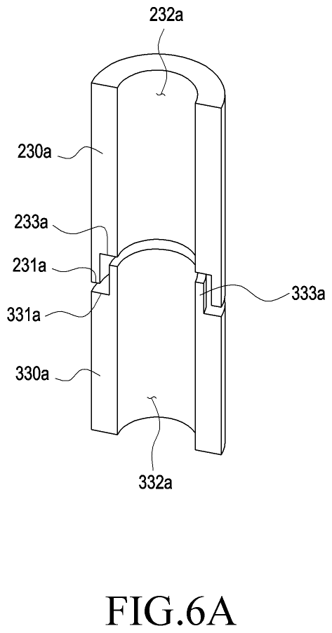

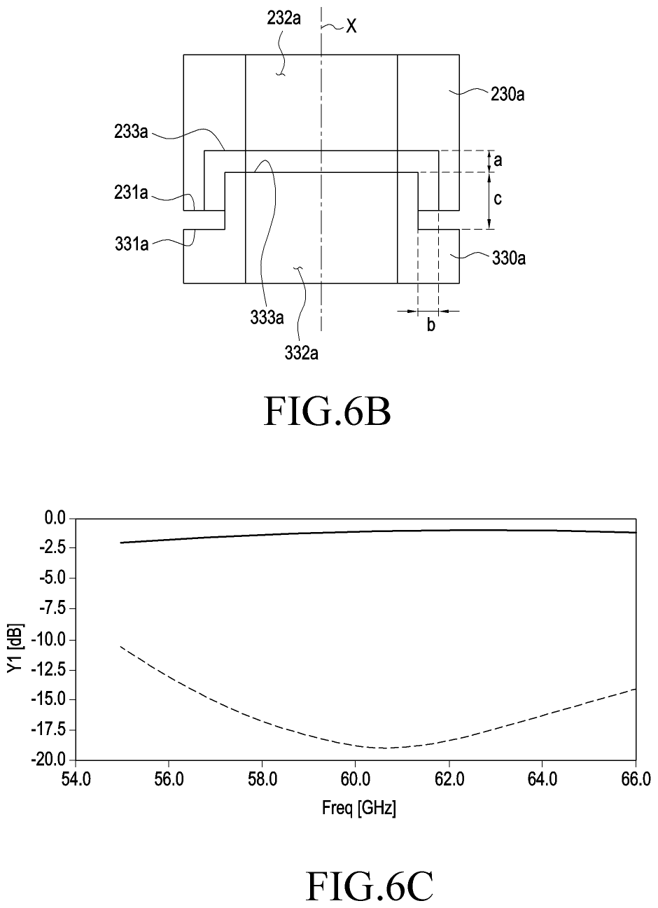

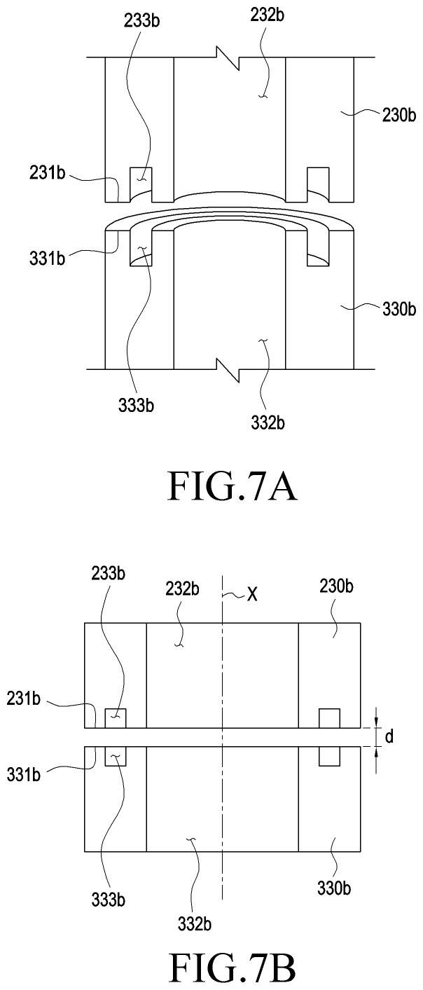

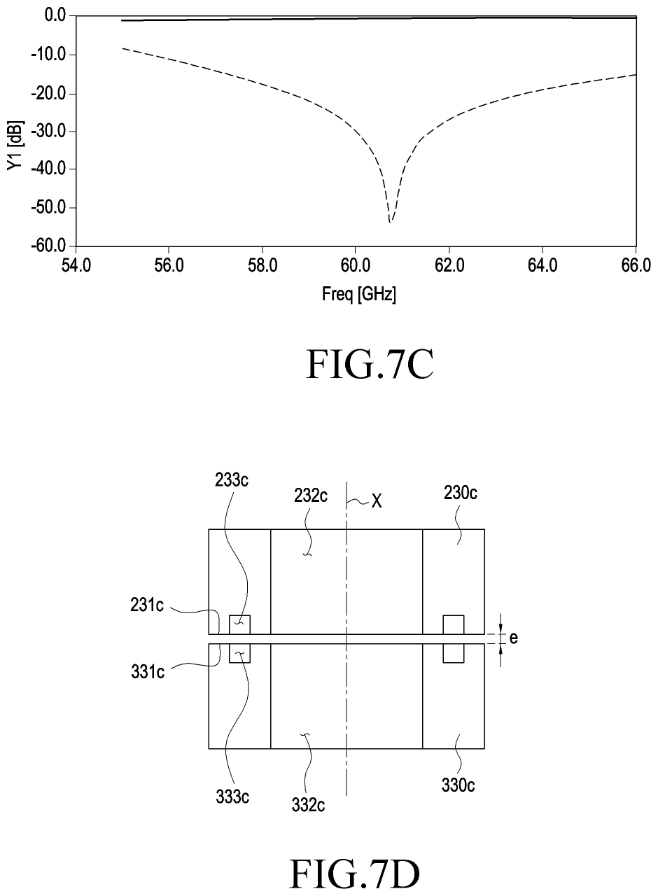

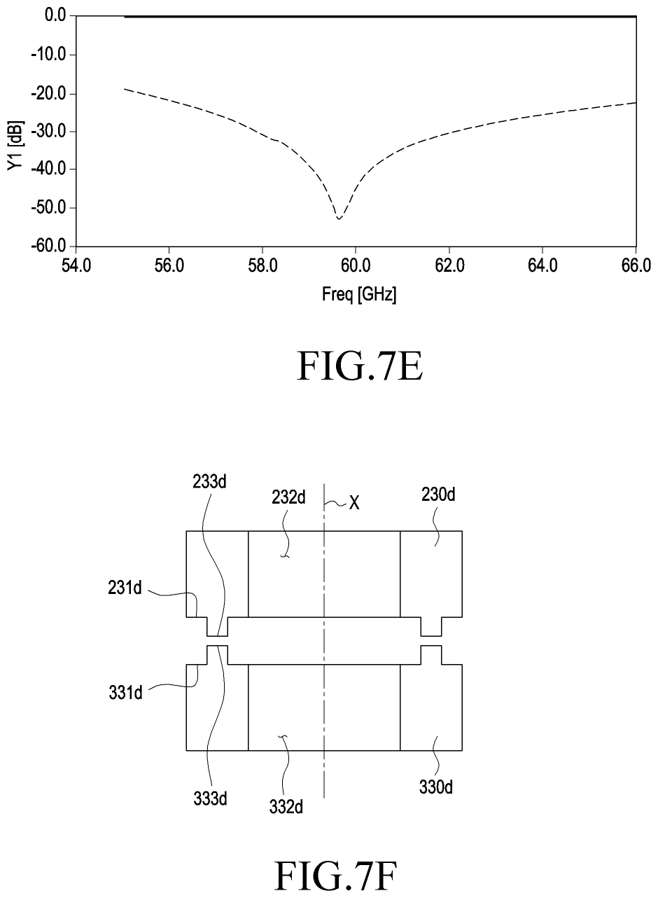

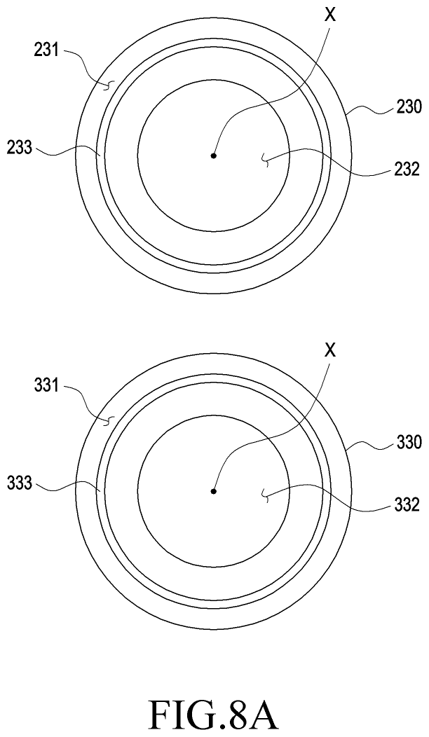

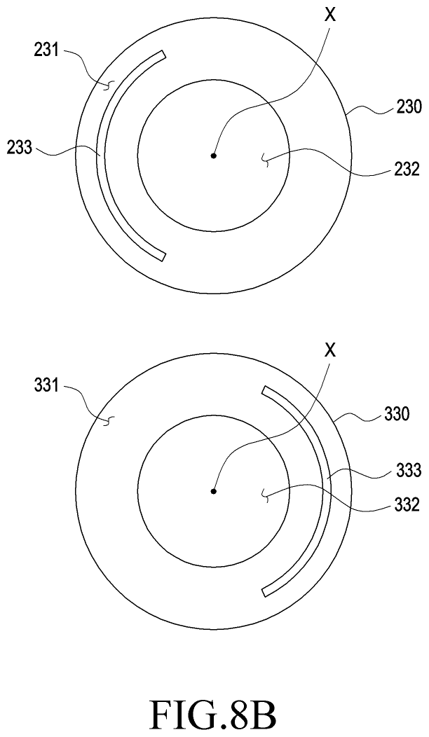

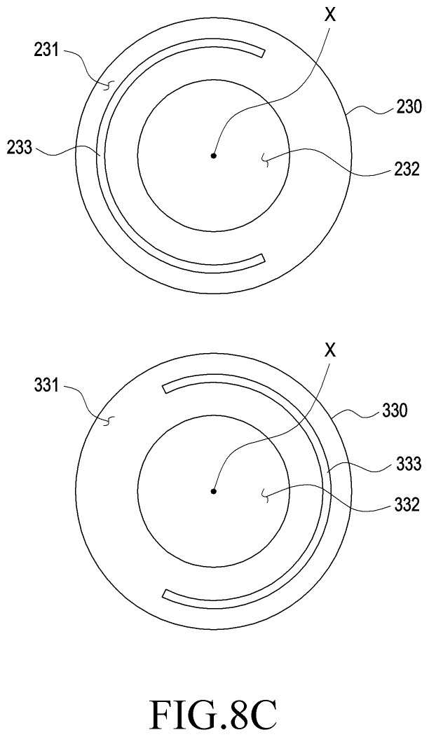

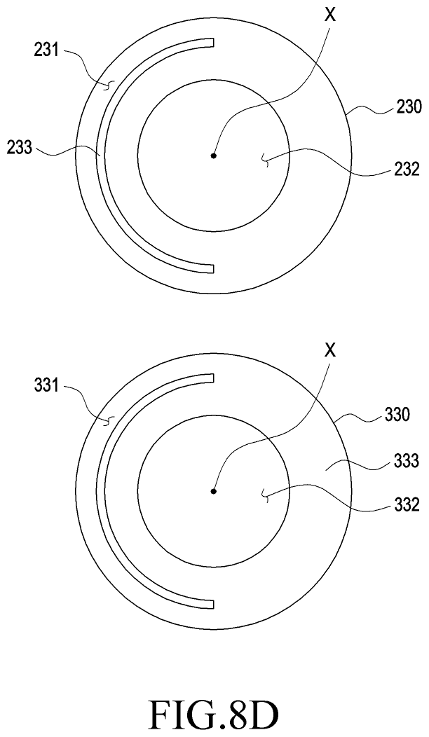

The first waveguide 230, which is a component supported by the first housing 210, may include an extension toward the second housing 310 in the hollow portion H. The second waveguide 330, which is a component supported by the second housing 310, may include an extension toward the first housing 210 in the hollow portion H. According to an embodiment, the extension of the first waveguide 230 and the extension of the second waveguide 330 may be aligned along the first rotation axis X, apart from each other by a predetermined distance (e.g., 0.5 mm or 1 mm) as a non-contact connection structure. In the non-contact connection structure of the first waveguide 230 and the second waveguide 330, the first waveguide 230 and the second waveguide 330 may be spaced from each other in various ways according to embodiments. As described later in detail, spacing structures between the first waveguide 230 and the second waveguide 330 may include a waveguide structure in which the first waveguide 230 and the second waveguide 330 are separated and inserted in the form of “ [symbol] ” as illustrated in FIG. 6A and an electromagnetic band gap (EBG)-based separate waveguide structure as illustrated in FIGS. 7A and 8A. For reference, the first waveguide and the second waveguide may be designed to be spaced from each other by a specific range of distances through impedance matching in later-described embodiments illustrated in FIGS. 6A, 7A and 8A. When data is transmitted/received through the first waveguide and the second waveguide kept apart from each other by a predetermined distance, the transmission characteristics of data communication may be changed according to the shape of the cross section of the first waveguide, the shape of the cross section of the second waveguide, and the distance between the cross section of the first waveguide and the cross section of the second waveguide. Therefore, to secure optimum transmission characteristics in a predetermined frequency range, the waveguides need to be designed according to the frequency characteristics in a fabrication process. Examples of the waveguides designed according to the frequency characteristics will be described later with reference to FIGS. 6A to 8A.

According to various embodiments of the disclosure, the robot 10 may perform power transmission/reception as well as data transmission/reception. The robot 10 may also transmit/receive power in the non-contact connection structure using the first coil 240 included in the first electronic device 200 and the second coil 340 included in the second electronic device 300.

The first coil 240 may be wound in a space provided by the first housing 210 and disposed toward the second housing 310, and the second coil 340 may be wound in a space provided by the second housing 310 and disposed toward the first housing 210. In the disclosure, as far as the coil 240 is configured to transfer power in a non-contact connection state with the second coil 340, the specific arrangement of the first coil 240 and the second coil 340 may configured in various ways according to embodiments of the disclosure. According to an embodiment, the first coil 240 may be disposed in the hollow portion H defined inside the stator 220, and the second coil 340 may be disposed in the hollow portion H defined inside the rotor 320, as illustrated in FIG. 3. The first coil 240 may be disposed in a space between an outer portion of the stator 220 and a sidewall (not shown) of the first housing 210, and the second coil 340 may be disposed in a space between an outer portion of the rotor 320 and a sidewall (not shown) of the second housing 310 in other embodiments.

The first coil 240 may be disposed outside the first waveguide 230. The second coil 340 may be disposed outside the second waveguide 330. The first coil 240 and the second coil 340 may transfer power to a wireless power receiver by one or more of inductive coupling based on electromagnetic induction generated by a wireless power signal and electromagnetic resonance coupling based on electromagnetic resonance generated by a wireless power signal in a specific frequency. According to various embodiments, the first coil 240 and the second coil 340 may transmit and receive wireless power in conformance to various wireless charging schemes (e.g., the scheme defined in the WPC standard (or Qi standard) or the scheme defined in the A4WP standard (or the AFA standard)). For example, electromagnetic induction-based wireless power transmission is a technique of transmitting power wirelessly using a primary coil and a secondary coil, in which power is transferred by inducting current to the other coil by a varying magnetic field generated through electromagnetic induction from one coil. Resonance coupling-based wireless power transmission is a technique of generating electromagnetic resonance in an electronic device by a wireless power signal transmitted by a wireless power transmitter and transferring power from the wireless power transmitter to the electronic device by the resonance phenomenon.

According to various embodiments of the disclosure, the robot 10 may further include at least one core (e.g., ferrite core) as a component for increasing the signal transmission/reception efficiency of the first coil 240 and the second coil 340. For example, the robot 10 may include the first ferrite core 250 surrounding at least a part of the first coil 240, and the second ferrite core 350 surrounding at least a part of the second coil 340. According to an embodiment, the first ferrite core 250 may be a core shaped into “U” including a recess recessed inward from one surface thereof, and may accommodate the first coil 240 in the recess. The second ferrite core 350 may also be a core shaped into “U” including a recess recessed inward from one surface thereof, and may accommodate the second coil 340 in the recess. As the robot 10 is provided with the first ferrite core 250 and the second ferrite core 350, leakage of a magnetic field generated between the first coil 240 and the second coil 340 may be prevented and/or reduced and the power transfer efficiency may be increased. Therefore, the decrease of the efficiency of data transmission/reception through the first waveguide 230 and the second waveguide 330 may be prevented and/or reduced.

Power transfer using the first coil 240 and the second coil 340 may be performed simultaneously with or at a different time from data transmission and reception using the first waveguide 230 and the second waveguide 330 or independently of or dependently on data transmission and reception using the first waveguide 230 and the second waveguide 330. For example, according to an embodiment, power transfer using the first coil 240 and the second coil 340 may be performed simultaneously with data transmission and reception using the first waveguide 230 and the second waveguide 330, as soon as the user engages the second electronic device 300 with the first electronic device 200. According to another embodiment, when the second electronic device 300 is engaged with the first electronic device 200, the first processor 201 may detect the engagement and perform power transfer using the first coil 240 and the second coil 340, and then the second processor 301 of the second electronic device 300 may wake up and perform data transmission/reception between the first waveguide 230 and the second waveguide 330.

According to various embodiments of the disclosure, the first electronic device 200 and the second electronic device 300 may include a first printed circuit board (PCB) 260 and a second PCB 360, respectively, and a first electronic part 270 and a second electronic part 370, respectively.

The first PCB 260 may be integrated with the first housing 210 or separately from the first housing 210 as illustrated in FIG. 3. Various electronic parts including the first electronic part 270 may be mounted on the first PCB 260. For example, the first electronic part 270 may include a processor (e.g., the first processor 201) and perform power transmission/reception control and/or management or data transmission/reception control and/or management through the processor. The first electronic part 270 may include at least one of the power inverter 245, the rectifier 345, or the PMU 202.

The second PCB 360 may also be integrated with the second housing 310 or separately from the second housing 310 as illustrated in FIG. 3. Various electronic parts including the second electronic part 370 may be mounted on the second PCB 360. For example, the second electronic part 370 may include a processor (e.g., the second processor 301) different from that of the first electronic part 270 and perform power transmission/reception control and/or management or data transmission/reception control and/or management through the processor. The second electronic part 370 may also include at least one of the power inverter 245, the rectifier 345, or the PMU 202.

According to various example embodiments, an electronic device may include: a first housing, a second housing configured to detachably and rotatably engage with the first housing upon a first rotation axis, and defining an inner space when engaged with the first housing, a first waveguide supported by the first housing and extending toward the second housing along the first rotation axis in the inner space, a second waveguide supported by the second housing, extending toward the first housing along the first rotation axis in the inner space, and aligned to be distanced from the first waveguide by a predetermined distance, a first coil disposed in the first housing and outside the first waveguide, and a second coil disposed in the second housing, outside the second waveguide at a position corresponding to the first coil.

According to various example embodiments, the first waveguide and the second waveguide are configured to transmit and receive a wireless communication signal therethrough.

According to various example embodiments, the first coil and the second coil are configured to transmit and receive wireless power therethrough.

According to various example embodiments, the electronic device may further include: a first ferrite core disposed in the first housing and surrounding at least a part of the first coil, and a second ferrite core disposed in the second housing and surrounding at least a part of the second coil.

According to various example embodiments, the second housing may include a driver (e.g., including a drive motor) and may be electrically coupled to an external power source.

According to various example embodiments, the second housing may be configured to rotate upon the first rotation axis by a hollow motor.

According to various example embodiments, the electronic device may include a plurality of first coils, and the plurality of first coils may be configured to transmit power to a plurality of second coils corresponding to the first coils, respectively.

According to various example embodiments, the electronic device may further include a power management unit comprising power management circuitry, the power management unit being configured to determine a power-related parameter for power to be transmitted through each of the plurality of first coils.

According to various example embodiments, the power-related parameter may include a voltage or a current of the power to be transmitted.

According to various example embodiments, the distance between the first waveguide and the second waveguide may be determined based on a frequency characteristic of a signal transmitted between the first waveguide and the second waveguide.

According to various example embodiments, an electronic device configured to rotatably engage with an adjacent electronic device including a first waveguide and a first coil disposed outside the first waveguide may include: a second waveguide aligned to be distanced from the first waveguide by a predetermined distance, a second coil disposed outside the second waveguide when the electronic device is engaged with the adjacent electronic device, and at a position corresponding to the first coil when the electronic device is engaged with the adjacent electronic device, and a rotation means (ex., motor) configured to rotate the electronic device upon a rotation axis with respect to the adjacent electronic device.

According to various example embodiments, the second waveguide may be configured to transmit and receive a wireless communication signal to and from the first waveguide.

According to various example embodiments, the second coil may be configured to transmit and receive wireless power to and from the first coil. According to various example embodiments, the electronic device may further include a ferrite core surrounding at least a part of the second coil.

FIG. 4 is a diagram illustrating an example non-contact connection structure between an electronic device (e.g., a first electronic device or a body unit) and a device (e.g., a second electronic device or an application unit) according to various embodiments of the disclosure.

As illustrated in FIG. 4, the non-contact connection structure may refer to a connection structure between the electronic device (e.g., the first electronic device or the body unit) 200 and the device (e.g., the second electronic device or the application unit) 300.

Referring to FIG. 4, as the electronic device 200 and the device 300 which are separate from each other are arranged close to each other and engaged with each other, when needed, data communication and power transmission may be performed between the electronic device 200 and the device 300. In the embodiment of FIG. 3, the electronic device 200 and the device 300 may be arranged close to each other and engaged with each other, as illustrated in FIG. 4.

According to the embodiment illustrated in FIG. 4, the motor M as a power source is disposed inside the electronic device 200. However, it is to be noted that the disclosure is not limited to the motor M disposed inside the electronic device 200, and a power source other than the motor M disposed inside the electronic device 200 may also fall within the scope of the disclosure. For example, the motor M may be disposed inside the device 300, not inside the electronic device 200, unlike FIG. 4. The motor M may be disposed outside the electronic device 200 and outside the device 300, unlike FIG. 4. FIG. 4 is a simplified diagram mainly illustrating the configurations of the first waveguide 230 and the second waveguide 330, with the first coil and the second coil omitted.

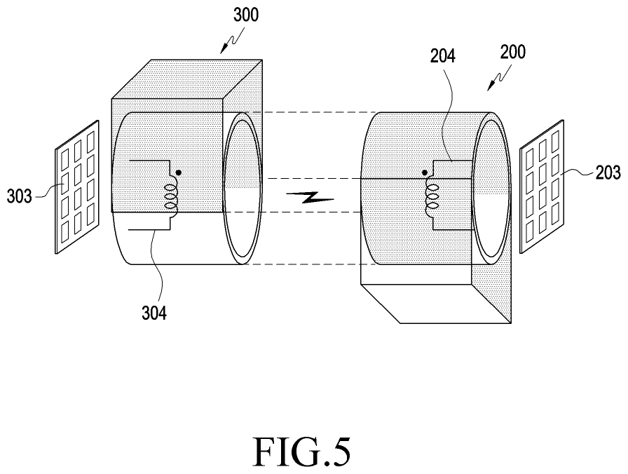

FIG. 5 is a diagram illustrating example coils added to the non-contact connection structure between the electronic device 200 (e.g., the first electronic device or the body unit) and the device 300 (e.g., the second electronic device or the application unit) illustrated in FIG. 3.

According to the embodiment illustrated in FIG. 5, the first wireless power transceiver 204 and the second wireless power transceiver 304 may be disposed respectively in the electronic device 200 and the device 300, and connected respectively to the first data communication module 203 and the second data communication module 303 at the same time in a non-contact manner.

The device 300 may be designed to be rotatable with respect to the electronic device 200, and a structure of transmitting power and data without loss between the electronic device 200 and the device 300 even during high-speed rotation and/or free rotation of the device 300 may be provided. Further, because the electronic device 200 is connected to the device 300 by wireless connection, not cable-based wired connection, assembly between the electronic device 200 and the device 300 is simple and there is no restriction on a rotation radius. An operation of the device 300 is not accompanied by an action such as cable bending and unbending. Accordingly, such a problem as non-contact of a cable and short circuit does not occur and a cable exposed outward is omitted, thereby providing a simple design and increasing compatibility between the electronic device 200 and the device 300.

FIG. 6A is a sectional perspective view illustrating an example first waveguide 230a (e.g., the first waveguide 230 in FIG. 3) and an example second waveguide 330a (e.g., the second waveguide 330 in FIG. 3). FIG. 6B is a side cross-sectional view illustrating the first waveguide 230a (e.g., the first waveguide 230 in FIG. 3) and the second waveguide 330a (e.g., the second waveguide 330 in FIG. 3). FIG. 6C is a graph illustrating the frequency characteristics of the embodiment illustrated in FIG. 6B.

One surface 231a of the first waveguide 230a and one surface 331a of the second waveguide 330a may oppose each other and may be aligned along the axis X. The axial alignment of the first waveguide 230a and the second waveguide 330a may lead to axial alignment of a first waveguide path 232a included in the first waveguide 230a and a second waveguide path 332a included in the second waveguide 330a. Referring to FIGS. 6A and 6B, a recess 233a may be formed at one side of the first waveguide 230a, opposing the second waveguide 330a, and a protrusion 333a may be formed at one side of the second waveguide 330a, opposing the first waveguide 230a. The protrusion 333a may be at least partially inserted into the recess 233a. In FIGS. 6A and 6B, the distances a and b between the recess 233a formed on the first waveguide 230a and the protrusion 333a formed on the second waveguide 330a may be set to values within a range from 0.5 mm to 2 mm. Compared to the recesses formed on the first ferrite core 250 and the second ferrite core 350, the recess 233a may be narrow in width and elongated along the surface 231a of the first waveguide 230a and the surface 331a of the second waveguide 330a.

For example, when the length c of the protrusion 333a formed on the second waveguide 330a is 1.75 mm and the distances a and b between the recess 233a formed on the first waveguide 230a and the protrusion 333a formed on the second waveguide 330a are 0.5 mm, the frequency characteristics of a signal transmitted from the first waveguide 230a to the second waveguide 330a are illustrated in FIG. 6C. For example, referring to FIG. 6C, for the signal transmitted from the first waveguide 230a to the second waveguide 330a, insertion loss measurements (marked with a solid line) may be about −1 dB or less across a total frequency band, and return loss measurements (marked with a dotted line) may be −15 B or less in the millimeter wave (mmWave) band of 57 GHz to 65 GHz. According to the structure illustrated in FIG. 6A, a signal in the frequency band of 57 GHz to 65 GHz may be effectively transmitted from the first waveguide 230a to the second waveguide 330a.

FIG. 7A is a sectional perspective view illustrating an example first waveguide 230b (e.g., the first waveguide 230 in FIG. 3) and an example second waveguide 330b (e.g., the second wave guide 330 in FIG. 3) according to an embodiment of the disclosure. FIG. 7B is a cross-sectional side view illustrating the first waveguide 230b (e.g., the first waveguide 230 in FIG. 3) and the second waveguide 330b (e.g., the second wave guide 330 in FIG. 3) according to an embodiment of the disclosure. FIG. 7C is a graph illustrating frequency characteristics of the embodiment illustrated in FIG. 7B. FIG. 7D is a cross-sectional side view illustrating an example first waveguide 230c (e.g., the first waveguide 230 in FIG. 3) and an example second waveguide 330c (e.g., the second waveguide 330 in FIG. 3) according to an embodiment of the disclosure. FIG. 7E is a graph illustrating frequency characteristics of the embodiment illustrated in FIG. 7D. FIG. 7F is a cross-sectional side view illustrating an example first waveguide 230d (e.g., the first waveguide 230 in FIG. 3) and an example second waveguide 330d (e.g., the second waveguide 330 in FIG. 3) according to an embodiment of the disclosure.

One surface 231b or 231c of each of the first waveguides 230b and 230c and one surface 331b or 331c of each of the second waveguides 330b and 330c may oppose each other, and may be aligned along the axis X. With the axial alignment of the first waveguides 230b and 230c and the second waveguides 330b and 330c, first waveguide paths 232b and 232c of the first waveguides 230b and 230c and second waveguide paths 333b and 333c included in the second waveguides 330b and 330c may also be axially aligned. Referring to FIGS. 7A, 7B and 7D, the surfaces 231b and 231c of the first waveguides 230b and 230c may be flat bottom surfaces into which recesses 233b and 233c of a predetermined width (e.g., 0.8 mm) are formed, respectively, and the surfaces 331b and 331c of the second waveguides 330b and 330c may be flat top surfaces into which recesses 333b and 333c of a predetermined width (e.g., 0.8 mm) are formed, respectively. The recesses 233b and 233c on the surfaces 231b and 231c of the first waveguides 230b and 230c may be formed at positions corresponding to the recesses 333b and 333c on the surfaces 331b and 331c of the second waveguides 330b and 330c.

Referring to FIGS. 7B and 7D, the distances d and e between the surfaces 231b and 231c of the first waveguides 230b and 230 and the surfaces 331b and 331c of the second waveguides 330b and 330c may be set to values within a range of about 0.5 mm to 1 mm. For example, FIG. 7B illustrates an embodiment in which the distance d between the surface 231b of the first waveguide 230b and the surface 331b of the second waveguide 330b is 1 mm. In the embodiment of FIG. 7B, the frequency characteristics of a signal transmitted from the first waveguide 230b to the second waveguide 330b are illustrated in FIG. 7C. For example, referring to FIG. 7C, for the signal transmitted from the first waveguide 230b to the second waveguide 330b, insertion loss measurements (marked with a solid line) may be about −0.2 dB or less across a total frequency band, and return loss measurements (marked with a dotted line) may be −10 dB or less in the frequency band of 57 GHz to 65 GHz. According to the structure illustrated in FIG. 7B, a signal in the frequency band of 57 GHz to 65 GHz may be effectively transmitted from the first waveguide 230b to the second waveguide 330b.

In another example, FIG. 7D illustrates an embodiment in which the distance d between the surface 231c of the first waveguide 230c and the surface 331c of the second waveguide 330c is 0.5 mm. In the embodiment of FIG. 7D, the frequency characteristics of the embodiment illustrated in FIG. 7D are illustrated in FIG. 7E. For example, referring to FIG. 7E, for the signal transmitted from the first waveguide 230c to the second waveguide 330c, insertion loss measurements (marked with a solid line) may be measured to be about −0.2 dB or less across a total frequency band, and return loss measurements (marked with a dotted line) may be −25 dB or less in the frequency band of 57 GHz to 65 GHz. According to the structure illustrated in FIG. 7D, a signal in the frequency band of 57 GHz to 65 GHz may be effectively transmitted from the first waveguide 230c to the second waveguide 330c.

Referring to FIGS. 7A, 7B, 7C, 7D and 7E (which may be referred to hereinafter as FIGS. 7A to 7E for convenience), the transmission characteristics of data communication may vary depending on the shapes of the cross sections of the first waveguides, the shapes of the cross sections of the second waveguides, and the distances between the cross sections of the first waveguides and the cross sections of the second waveguides. Therefore, in order to match the transmission characteristics of data communication with predetermined required transmission characteristics according to the design specification of the robot 10, the shape of the cross section of a first waveguide, the shape of the cross section of a second waveguide, and the distance between the cross sections of the first and second waveguides may be set to various values. For example, impedance matching may be considered in designing the shape of the cross section of the first waveguide, the shape of the cross sections of the second waveguide, and the distance between the cross section of the first waveguide and the cross section of the second waveguide. Since each of the first waveguide and the second waveguide serves as a transmission line through which a signal in a specific frequency band is transmitted, when impedance mismatching occurs between the first waveguide and the second waveguide, the resulting signal reflection may cause power loss. Accordingly, power loss may be minimized during transmission by designing the shapes of the first waveguide and the second waveguide and the distance between the first waveguide and the second waveguide so that impedance matches between the first waveguide and the second waveguide.

According to the embodiments illustrated in FIGS. 7A to 7E, the first waveguides and the second waveguides with the recesses 233b, 233c, 333b, and 333c formed thereon have been described mainly. In the above-described embodiments, the recesses 233b, 233c, 333b, and 333c may include all similar shapes such as grooves, holes, slits, and openings. In the above-described embodiments, each of the recesses 233b, 233c, 333b, and 333c is disclosed as a hollow relief, not limiting the scope of the disclosure.

Referring to FIG. 7F, for example, in another embodiment, regarding the first waveguide 230d and the second waveguide 330d in which waveguide paths 232d and 332d facing each other are aligned along the axis X, the first waveguide 230d may be disclosed as having a protrusion 233d in the form of a relief on one surface 231d thereof, and the second waveguide 330d may be disclosed as having a protrusion 333d on one surface 331d thereof, corresponding to the protrusion 233d. The protrusions 233d and 333d illustrated in FIG. 7F do not pass through the center of the axis, unlike the protrusions 233a and 333a illustrated in FIG. 6A, and may be formed to be at least partially ring-shaped. In various embodiments of the disclosure, the description of recesses may be applied to the protrusions 233d and 333d illustrated in FIG. 7F.

FIG. 8A is a diagram illustrating example recesses 233 and 333 formed in the first waveguide 230 (e.g., the first waveguide 230 of FIG. 3) and a second waveguide 330 (e.g., the second waveguide 330 of FIG. 3) according to an embodiment of the disclosure. FIG. 8B is a diagram illustrating example recesses 233 and 333 formed in a first waveguide 230 (e.g., the first waveguide 230 of FIG. 3) and a second waveguide 330 (e.g., the second waveguide 330 of FIG. 3) according to an embodiment of the disclosure. FIG. 8C is a diagram illustrating example recesses 233 and 333 formed in a first waveguide 230 (e.g., the first waveguide 230 of FIG. 3) and a second waveguide 330 (e.g., the second waveguide 330 of FIG. 3) according to an embodiment of the disclosure. FIG. 8D is a diagram illustrating example recesses 233 and 333 formed in a first waveguide 230 (e.g., the first waveguide 230 of FIG. 3) and a second waveguide 330 (e.g., the second waveguide 330 of FIG. 3) according to an embodiment of the disclosure. FIGS. 8A, 8B, 8C and 8D (which may be referred to hereinafter as FIGS. 8A to 8D for convenience) may illustrate the first waveguides 230 and the second waveguides 330, viewed from a direction parallel to the axis X according to various embodiments.

As illustrated in FIG. 8A, ring-shaped recesses 233 and 333 may be formed on the first waveguide 230 and the second waveguide 330, respectively. The recess 233 formed on the first waveguide 230 and the recess 333 formed on the second waveguide 330 may have matching widths and matching diameters and may be formed at matching positions, when seen from above surfaces 231 and 331 of the first waveguide 230 and the second waveguide 330. According to various embodiments, the width of the recess 233 formed on the first waveguide 230 may be equal to or different from the width of the recess 333 formed on the second waveguide 330, and the waveguides 230 and 330 may surround the waveguide paths 232, 332 respectively.

According to various embodiments, referring to FIGS. 8B and 8C, arc-shaped or curved recesses 233 and 333 may be formed on the first waveguide 230 and the second waveguide 330, respectively. As illustrated in FIGS. 8B and 8C, the lengths of the circumferences of the arcs of the recesses 233 and 333 may be set to various values.

Referring to FIGS. 8B to 8D together, the recesses 233 and 333 formed on the first waveguide 230 and the second waveguide 330 may include left and right recesses symmetrical with respect to a virtual plane including the axis X (e.g., the recesses 233 and 333 in FIGS. 8B and 8C) or recesses symmetrical with respect to a virtual plane perpendicular to the axis X (e.g., the recesses 233 and 333 in FIG. 8D).

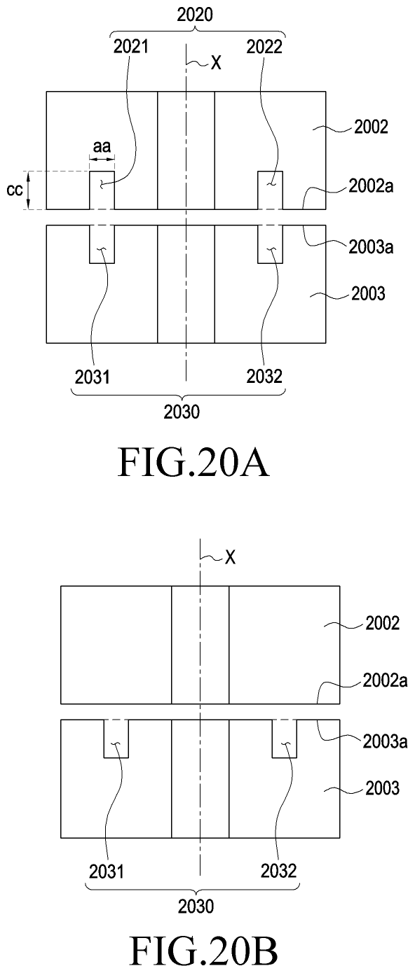

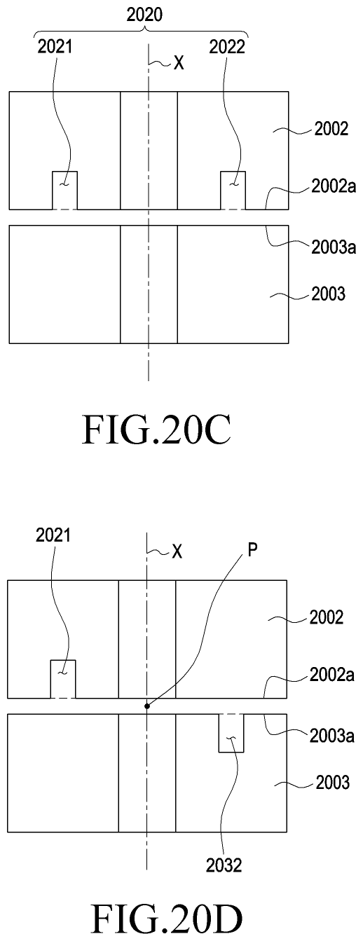

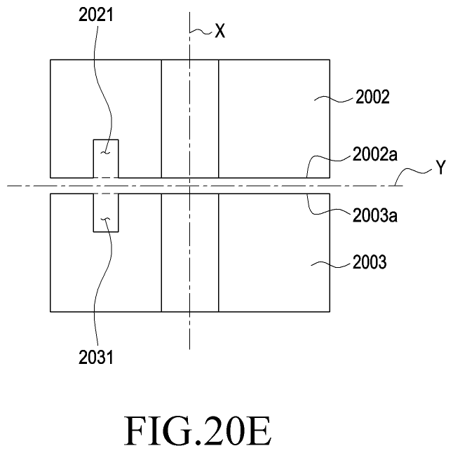

In addition to the above-described embodiments, more various embodiments of a first waveguide (e.g., the first waveguide 230 in FIG. 3) and a second waveguide (e.g., the second waveguide 330 in FIG. 3) will be described in greater detail below with reference to FIGS. 20 to 23.

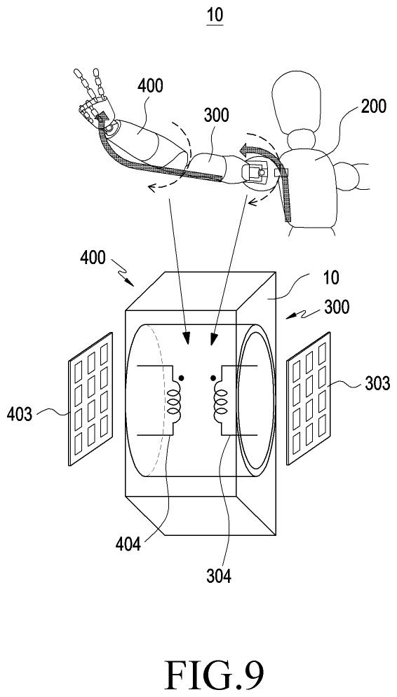

FIG. 9 is a diagram illustrating an example non-contact connection structure between an electronic device (e.g., the first electronic device or the body unit) and a device (e.g., the second electronic device or the application unit) according to various embodiments of the disclosure.

As illustrated in FIG. 9, the electronic device 200 forming the body of the robot 10 may be connected to a plurality of devices 300 and 400. The electronic device 200 and the device 300 may be directly connected to each other by the non-contact connection structure described before with reference to FIGS. 3 to 8. Likewise, the device 300 and another device 400 may be directly connected to each other by the non-contact connection structure described before with reference to FIGS. 3 to 8. In this case, the electronic device 200 and the device 400 may be connected indirectly through the device 300.

According to the embodiment illustrated in FIG. 9, the second wireless power transceiver 304 and a third wireless power transceiver 404 may be disposed in the device 300 and the other device 400, respectively. The second wireless power transceiver 304 and the third wireless power transceiver 404 may be connected in a non-contact manner simultaneously with connection between the second data communication module 303 and a third data communication module 403 disposed in the device 300 and the other device 400, respectively.

With respect to the electronic device 200, the device 400 as well as the device 300 may be designed to be rotatable at a high speed. During high-speed rotation and/or free rotation of the device 300 and the other device 400, power and data may be transmitted without loss between the electronic device 200 and the device 300 or between the device 300 and the other device 400.

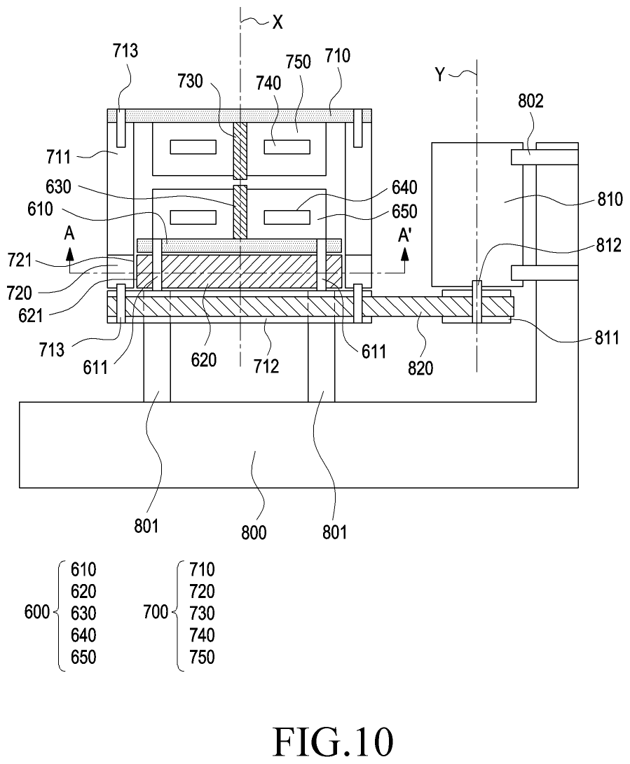

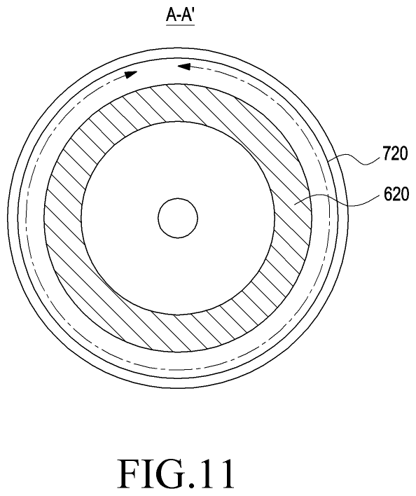

FIG. 10 is a diagram illustrating an example non-contact connection structure between an electronic device (e.g., the first electronic device or the body unit) and a device (e.g., the second electronic device or the application unit) according to another embodiment of the disclosure. FIG. 11 is a cross-sectional diagram illustrating an example non-contact connection structure between the electronic device (e.g., the first electronic device or the body unit) and the device (e.g., the second electronic device or the application unit), taken along line A-A′ illustrated in FIG. 10.

Referring to FIG. 10, a non-contact connection structure between an electronic device (e.g., a first electronic device or a body unit) 600 and a device (e.g., a second electronic device or an application unit) 700 may include a first housing 610, a first waveguide 630, a first coil 640, a second housing 710, a second waveguide 730, and a second coil 740.

Referring to FIG. 10, in an embodiment, the first electronic device 600 may include the first housing 610, a first bearing 620, the first waveguide 630, the first coil 640, and a first ferrite core 650. The second electronic device 700 may include the second housing 710, a second bearing 720, the second waveguide 730, the second coil 740, and a second ferrite core 750. According to various embodiments, some components may be omitted or replaced with other components, or one or more other components may be added, in the first electronic device 600 or the second electronic device 700.

The first housing 610 may be configured to support the first waveguide 630, the first coil 640, and so on. The first housing 610 may be configured to provide an area (or space) in which the first waveguide 630 and the first coil 640 are disposed in the first electronic device 600. The first housing 610 is not limited to any particular shape.

According to an embodiment, the first housing 610 may have a structure that provides a space in which components such as the first waveguide 630 and the first coil 640 are accommodated. The first housing 610 may be formed in a simple, at least partially flat plate structure. The first housing 610 may be supported by an external device (or structure) 800 provided outside the first electronic device 600 and the second electronic device 700. For example, the first housing 610 may be supported by the external device 800 through at least one support 801. A connection member 611 may be additionally disposed at one side of the support 801 to fix the first housing 610 to the support 801.

The second housing 710 may provide a space for accommodating components such as the first waveguide 630, the first coil 640, the second waveguide 730, and the second coil 640 therein, when being engaged with the first housing 610. The second housing 710 may be configured to support the second waveguide 730, the second coil 740, and so on. According to an embodiment, the second housing 710 may be configured to support the second bearing 720. The second housing 710 may be similar to the first housing 610 in structure and function. The second housing 710 may have a ‘cover’ structure for protecting the components against external physical, chemical, and electrical shocks.

The first housing 610 and the second housing 710 may be formed to be detachably engaged with each other. For example, the user may simply fasten the second housing 710 of the second electronic device 700 with the first housing 610 of the first electronic device 600. A configuration for fastening the first housing 610 with the second housing 710 may include the bearings 620 and 720. Referring to FIGS. 5 and 11 together, in the non-contact connection structure between the first electronic device 600 and the second electronic device 700, the first bearing 620 may be disposed at the center of the rotation axis X, and the second bearing 720 may be disposed to surround the first bearing 620. The first bearing 620 and the second bearing 720 may function to constantly fix the central axis of the second electronic device 700 on the rotation axis X during rotation of the second electronic device 700, and rotate the second electronic device 700, while supporting load applied to the axis.

A robot (e.g., the robot 10 in FIG. 1) according to an embodiment may include a power source 810 as a component included in the external device (or mechanism) 800 outside the first electronic device 600 and the second electronic device 700. The power source 810 may be supported by a support 802 of the external device 800 and fixedly provided at one side of the external device 800. While not shown, a processor for driving the power source 810 may be provided in another component included in the first electronic device 600, the second electronic device 700, the external device 800, and/or the robot (e.g., the robot 10 in FIG. 1), and control on/off of the power source 810.

The second housing 710 may further include a gear 712 (or pulley) as a rotation means (ex., motor) connected to the power source 810. The second housing 710 may further include a cover member 711 which is connected to the second housing 710 by at least one fixing means 713 and forms a space between the first housing 610 and the second housing 710. The second bearing 720 may be provided on one surface of the cover member 711, and the inner circumferential surface 721 of the second bearing 720 may be aligned to contact the outer circumferential surface 621 of the first bearing 620. The second bearing 720 may be fixedly connected to the gear 712. The power source 810 and the gear 712 may be connected to each other indirectly through the belt 820, and power generated from the power source 810 may be transferred to the gear 712 through the belt 820. When a shaft 811 connected to the power source 810 by a fixing pin 812 rotates around a rotation axis Y, the belt 820 may rotate in one direction, and the force transmitted from the belt 820 may rotate the gear 712 in one direction. Since the gear 712 is fixedly connected to the second bearing 720, the entire second housing 710 may rotate around the rotation axis X during the rotation of the gear 712.

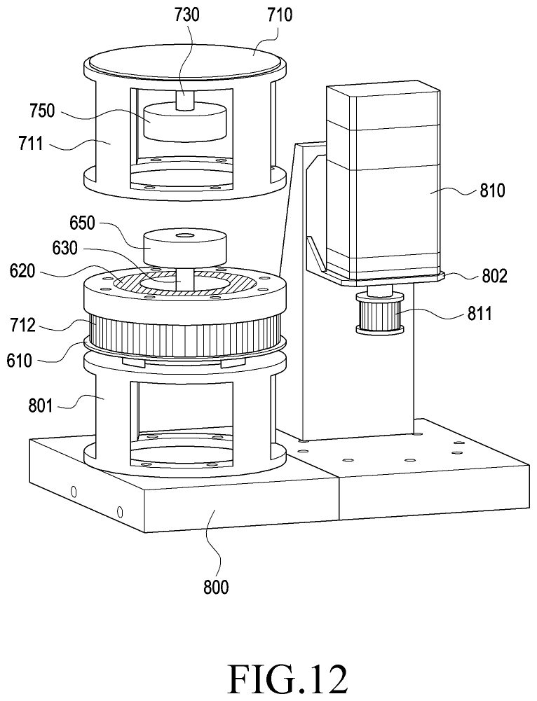

FIG. 12 is a perspective view illustrating example engagement between the first electronic device 600 and the second electronic device 700 according to the embodiment illustrated in FIG. 10.

According to an embodiment, the first electronic device 600 and the second electronic device 700 in a separate state may be engaged with each other, when needed. Alternatively, the second electronic device 700, which is connected to the first electronic device 600 at one portion and separate from the first electronic device 700 at the remaining portion, may be connected to the first electronic device 600 at the remaining portion, as illustrated in FIG. 12. The cross section illustrated in FIG. 10 may correspond to the state after the first electronic device 600 is engaged with the second electronic device 700.

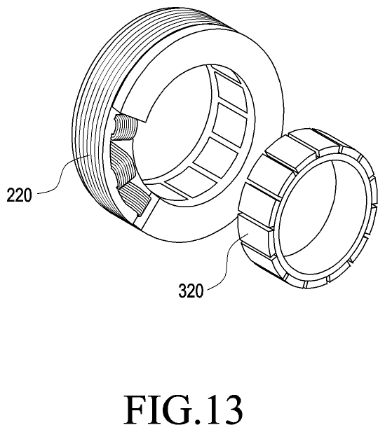

FIG. 13 is a diagram illustrating an example hollow motor according to various embodiments of the disclosure.

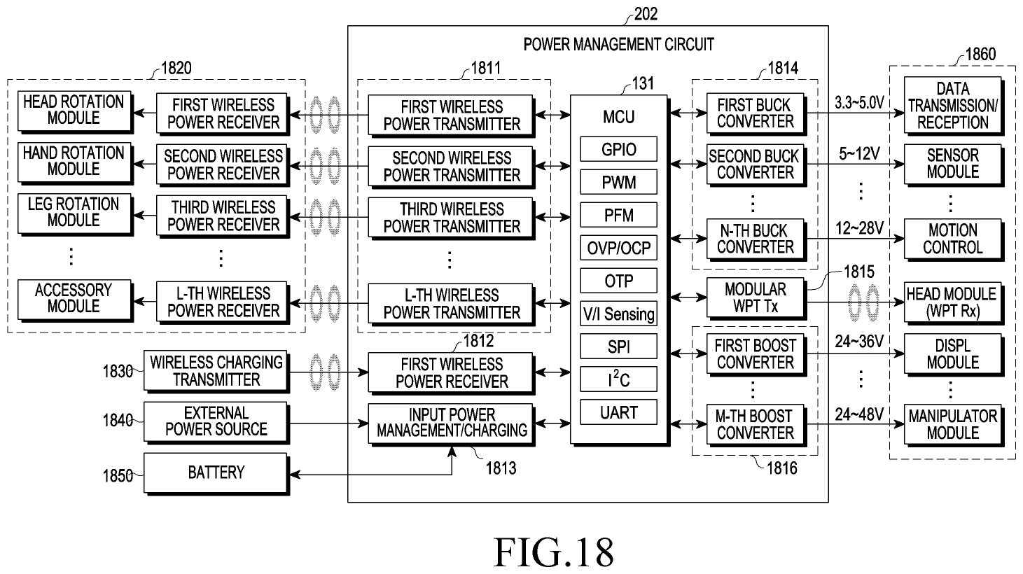

According to the embodiment illustrated in FIG. 13, the hollow motor is shown as having the stator 220 disposed outside and the rotor 320 disposed inside. The hollow motor with the stator disposed inside and the rotor disposed outside may also be applied to various embodiments of the disclosure. In another example, the stator and the rotor may be stacked with each other in the hollow motor. For example, the motor M including the stator 220 and the rotor 320 illustrated in FIG. 3 may be an example of the hollow motor illustrated in FIG. 18.

In summary, in the embodiment illustrated in FIG. 10 the power source 810 is located outside the first electronic device 600 and the second electronic device 700, and only the gear 712 is disposed to transfer power from the external power source 810, rather than a motor being disposed in the first housing 610 and/or the second housing 710. In the embodiment illustrated in FIG. 3 the first housing 610 and/or the second housing 710 has its own power source M. As such, the power generation and transmission configuration of the disclosure may vary according to embodiments. In other words, it should be noted that the non-contact connection structure according to various embodiments of the disclosure may adopt various other power transmission mechanisms, not limited to the power transmission mechanisms according to the embodiments illustrated in FIGS. 3 and 10.

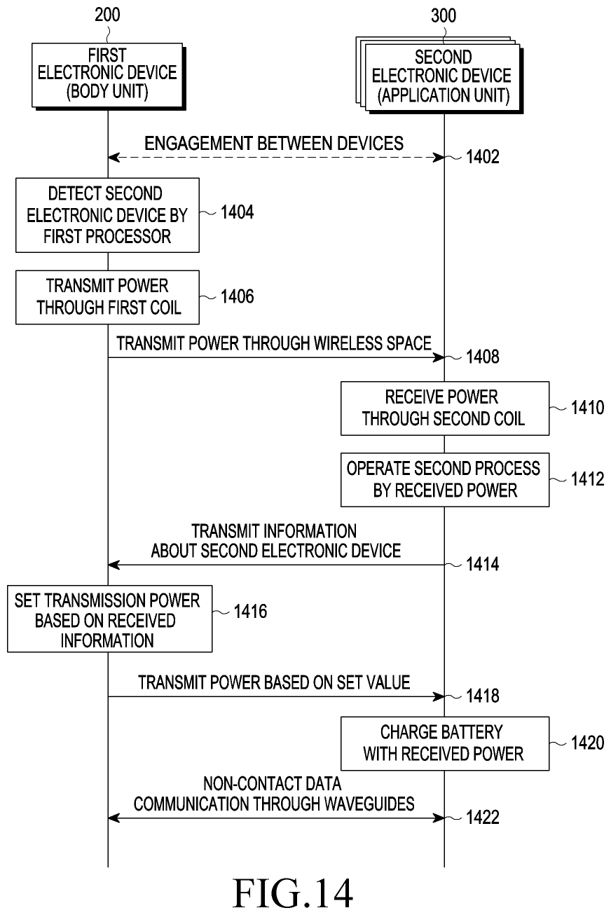

FIG. 14 is a signal flow diagram illustrating example operation of an electronic device according to an embodiment of the disclosure. Referring to FIG. 14, in operation 1402, when at least one (e.g., an application unit) of a plurality of second electronic devices 300 is engaged with the first electronic device 200 (e.g., a body unit), the first electronic device 200 may detect the second electronic device 300 in operation 1404 and control transmission of predetermined power (e.g., first power) to the second electronic device 300 through the first coil 240 of the first wireless power transceiver 204 in operation 1406 and operation 1408. According to various embodiments, the predetermined power may be a signal (e.g., a ping signal or a beacon signal) conforming to various wireless charging schemes (e.g., the scheme defined in the WPC standard (or Qi standard) or A4WP standard (or AFA standard)). The predetermined power transmitted from the first electronic device 200 may be power of a magnitude set to operate the second processor 301 of the second electronic device 300. When the power is transmitted through a wireless space from the first electronic device 200 to the second electronic device 300 in operation 1408, the second wireless power transceiver 304 of the second electronic device 300 may receive the power from the first coil 240 of the first wireless power transceiver 204 through the second coil 340 in operation 1410.

According to various embodiments, in operation 1412, the second processor 301 of the second electronic device 300 may be operated by the power received through the second wireless power transceiver 304. For example, when the battery 302 of the second electronic device 300 is discharged (e.g., in a dead battery state) and thus the second processor 301 is off, the second processor 301 may wake up by the power received through the second wireless power transceiver 304 and operate normally.

According to various embodiments, as the second processor 301 of the second electronic device 300 is operated, the second processor 301 of the second electronic device 300 may transmit data to the first electronic device 200 through the second data communication module 303 in operation 1414. The data transmitted from the second processor 301 may include information related to the second electronic device 300 (e.g., the ID of the second electronic device 300, the type of the second electronic device 300, information about required power for the second electronic device 300, information about a voltage or current related to charging power of the second electronic device 300, and rating information (e.g., effective value) about the second electronic device). According to various embodiments, the first processor 201 of the first electronic device 200 may receive the information related to the second electronic device 300 from the second electronic device 300 through the first data communication module 203.

In operation 1416, the first processor 201 of the first electronic device 200 may determine parameters related to power to be transmitted to the second electronic device 300 based on the information received from the second electronic device 300 (e.g., a voltage or current of the power to be transmitted) according to a predetermined algorithm. For example, when the first electronic device 200 is engaged with a plurality of second electronic devices 300 and 400 and simultaneously transmits power to the plurality of second electronic devices 300 and 400, the PMU 202 of the first electronic device 200 may apply a predetermined algorithm offering an optimal charging efficiency based on data received from the plurality of second electronic devices 300 and 400.

According to various embodiments, the first wireless power transceiver 204 of the first electronic device 200 may generate power according to the parameters related to power determined by the first processor 201, and transmit the generated power (e.g., second power) to the wireless space through the first coil 240 in operation 1418. The second wireless power transceiver 304 of the second electronic device 300 may receive the power from the first coil 240 of the first wireless power transceiver 204 through the second coil 340. The second wireless power transceiver 304 of the second electronic device 300 may convert the AC power received through the second coil 340 to a DC signal through the rectifier 345. In operation 1420, the second electronic device 300 may charge the battery 302 with the power converted to the DC signal by the rectifier 345.

According to various embodiments, the second processor 301 of the second electronic device 300 may perform a specific operation of the second electronic device 300 by the power received from the first electronic device 200. For example, in operation 1422, the second electronic device 300 may transmit data to and receive data from the first data communication module 203 of the first electronic device 200 through the second data communication module 303 (e.g., the second waveguide 330).

According to various example embodiments, a method of operating an electronic device may include: detecting an external device in response to engagement with the external device, transmitting first power to operate a processor of the external device through a first coil, receiving information about the external device from the external device based on the operation of the processor of the external device, determining a power-related parameter for power to be transmitted to the external device based on the information received from the external device, transmitting second power through the first coil based on the determined power-related parameter, and transmitting and receiving data to and from a second waveguide of the external device through a first waveguide.

According to various example embodiments, when the electronic device is engaged with the external device, the first waveguide may be aligned to be distanced from the second waveguide by a predetermined distance.

According to various example embodiments, the information about the external device may include at least one of an ID of the external device, information about a type of the external device, information about required power for the external device, information about a voltage or a current related to charging power of the external device, or rating information about the external device.

According to various example embodiments, the detection of an external device may include detecting the external device based on a change in a signal transmitted from the electronic device through the first coil.

According to various example embodiments, the detection of an external device may include identifying whether the external device is engaged with the electronic device through a hall sensor disposed at a position near to the external device.

According to various example embodiments, the power-related parameter may include a voltage or a current of the power to be transmitted.

FIG. 15 is a block diagram illustrating an example electronic device according to various embodiments.

Referring to FIG. 15, an electronic device 101 (e.g., the first electronic device 200) according to various embodiments may include at least one of an interface (e.g., including interface circuitry) 103, a wireless charging module (e.g., including wireless charging circuitry) 104, a battery 105, a processor (e.g., including processing circuitry) 120, the PMU 202, and/or a plurality of (e.g., N) loads 140a, 140b, 140c, and 140n.

According to various embodiments of the disclosure, the plurality of loads 140a, 140b, 140c, and 140n may include the afore-described plurality of devices 300 and 400, and may be modules or accessories attachable to the interior or exterior of a robot, additionally or alternatively to other components of the electronic device 200, for function extension and/or application modification in the robot. The plurality of loads 140a, 140b, 140c, and 140n may be separate electronic devices distinguished from the electronic device 200. According to an embodiment, the plurality of loads 140a, 140b, 140c, and 140n may execute or invoke a function independently of the electronic device 200. According to various embodiments, while the plurality of loads 140a, 140b, 140c, and 140n are shown as configured separately from the electronic device 200, the loads 140a, 140b, 140c, and 140n may be combined with the electronic device 200 into one electronic device (e.g., one unified whole robot).

For example, the electronic device 101 (the first electronic device) may correspond to the body unit of the robot, and each of the plurality of loads 140a, 140b, 140c, 140n may be, as an application unit detachably engaged with the body of the robot, a robot head, a robot arm, a robot hand, a robot driver, another accessory, a manipulator, or a display. Other configurations capable of executing various functions may be included in the plurality of loads 140a, 140b, 140c, and 140n. According to various embodiments, the plurality of loads 140a, 140b, 140c, and 140n may include various modules or circuits (e.g., the first processor 201, the first data communication module 203s, and the first wireless power transceivers 204) configured in the electronic device 200 described before with reference to FIG. 2.

The interface 103 according to various embodiments may include various interface circuitry and be connected wiredly to an external power source, and transmit power from the external power source to the PMU 202. The interface 103 may be implemented, for example, as a connector for connecting a cable for power supply or as a cable for supplying power and a connector for connecting the cable to the external power source. For example, the interface 103 may be implemented as, but not limited to, any of various USB types of connectors. When receiving DC power from the external power source, the interface 103 may transmit the received DC power to the PMU 202 with or without conversion of the magnitude of the voltage of the DC power. When receiving AC power from the external power source, the interface 103 may convert the AC power to DC power and/or convert the magnitude of the voltage of the AC power and transmit the converted power to the PMU 202.

The wireless charging module 104 according to various embodiments may include various wireless charging circuitry and be implemented in a manner defined in the WPC standard (or Qi standard) or the A4WP standard (or AFA standard). The wireless charging module 104 may include a coil that generates induced electromotive force by a nearby magnetic field with a magnitude varying over time. The process of generating the induced electromotive force through the coil may be expressed as wireless power reception of the wireless charging module 104. The wireless charging module 104 may include at least one of a receiving coil, at least one capacitor, an impedance matching circuit, a rectifier, a DC-to-DC converter, or a communication circuit.

The communication circuit may be implemented as an in-band communication circuit of an on-off keying modulation/demodulation type, or an out-of-band communication circuit (e.g., a Bluetooth low energy (BLE) communication module). According to various embodiments, the wireless charging module 104 may receive RF waves beamformed in an RF manner. Depending on implementation, the wireless charging module 104 may not be included in the electronic device 101.

The battery 105 according to various embodiments may be implemented as a rechargeable secondary battery. The battery 105 may be charged with, for example, power received through the interface 103 and/or power received through the wireless charging module 104. While not shown, according to various embodiments, the interface 103 and/or the wireless charging module 104 may be connected to a charger (or converter) (not shown), and the battery 105 may be charged with power adjusted by the charger. The charger and/or the converter may be implemented as an element independent from the PMU 202, or as at least a part of the PMU 202. The battery 105 may transfer stored power to the PMU 202. Power from the interface 103 and/or power from the wireless charging module 104 may be transferred to the battery 105 and/or the PMU 202.

The processor 120 according to various embodiments may, for example, include various processing circuitry and execute software to control at least one other component (e.g., hardware or software component) of the electronic device 101 connected to the processor 120, and perform various data processes and computations. For example, the processor 120 may control other components such as a load (e.g., the first to N^{th} loads 140a, 140b, 140c, 140n) and/or a micro controller unit (MCU) 131, and receive and process data from the load (e.g., the first to N^{th} loads 140a, 140b, 140c, 140n) and/or the MCU 131. The processor 120 may load a command or data received from other loads (e.g., an input device, a sensor module and/or a communication module) to a volatile memory (e.g., random access memory (RAM)), process the command or data, and store the result data in a non-volatile memory (e.g., NAND).

According to an embodiment, the processor 120 may include a main processor (e.g., a central processing unit (CPU) or application processor (AP)), and an auxiliary processor (e.g., a graphic processing device, an image signal processor, a sensor hub processor, or a communication processor) which independently operates, uses less power than the main processor additionally or alternatively, or is specialized for a designated function. The auxiliary processor may be operated separately from the main processor or embedded in the main processor. That is, a plurality of chips or circuits capable of performing computations may be included in the electronic device 101. The auxiliary processor may control at least a part of functions or states related to at least one load (e.g., an output device, the sensor module, or the communication module) among the components of the electronic device 101, for example, on behalf of the main processor while the main processor stays in an inactive (e.g., sleep) state or together with the main processor while the main process stays in an active (e.g., application execution) state. According to an embodiment, the auxiliary processor (e.g., the image signal processor or the communication processor) may be implemented as a component of another functionally related load (e.g., a camera or the communication module).

A memory (not shown) may store various data used by at least one component (e.g., the processor 120 or the sensor module) of the electronic device 101, for example, software and input data or output data for a related command. The memory (not shown) may include a volatile memory or a non-volatile memory. According to various embodiments, the memory (not shown) may store information about task execution conditions corresponding to various tasks. The electronic device 101 may store, for example, a task execution condition mapped to each piece of user identification information. The memory (not shown) may store load control information for various operations of the electronic device 101. The processor 120 may control a driving circuit to output computed information or move to another point based on information obtained based on a load (e.g., the sensor module or a communication circuit). According to various embodiments, at least some programs for the operations of the electronic device 101 may be stored in an external device (e.g., a server). In this case, the electronic device 101 may transmit a query to the external device, and the external device may generate a response using data included in the query and transmit the response to the electronic device 101.

In this disclosure, when it is described that the electronic device 101 performs a specific operation, this may refer, for example, to various loads included in the electronic device 101, for example, control circuits such as the processor 120 and/or the MCU 131 or other loads performing the specific operation. As the control circuits or other loads perform the specific operation, power may be consumed. Alternatively, when it is described that the electronic device 101 performs a specific operation, this may refer, for example, to the processor 120 and/or the MCU 131 controlling other loads to perform the specific operation. Alternatively, when it is said that the electronic device 101 performs a specific operation, this may imply that as an instruction for performing the specific operation stored in a storage circuit (e.g., the memory) is executed, the instruction causes the processor 120 and/or the MUC 131 or other loads to perform the specific operation, or the instruction is stored in the storage circuit.

The PMU 202 according to various embodiments may include a plurality of (e.g., M) regulators 132a, 132b, 132c, and 132m. The number (e.g., M) of the regulators 132a, 132b, 132c, and 132m may be equal to, less than, or larger than the number (e.g. N) of a plurality of ports 134a, 134b, 134c, . . . , 134n. Each of the plurality of (e.g., M) regulators 132a, 132b, 132c, and 132m may regulate and output received power. For example, each of the plurality of (e.g., M) regulators 132a, 132b, 132c, and 132m may output the received power by adjusting at least one of the magnitude of the current and/or the magnitude of the voltage of the received power. Each of the plurality of (e.g., M) regulators 132a, 132b, 132c, and 132m may suppress (or cancel) noise (or ripple). Each of the plurality of (e.g., M) regulators 132a, 132b, 132c, and 132m may be of the same type as, for example, a linear dropout (LDO) regulator (e.g., RT 9011 model or AP 7343 model) or a step down regulator (for example, LM 3655 model or TPS 54331 model). However, those skilled in the art will understand that the regulators are not limited to any particular type and any particular regulator model.

According to various embodiments, at least a part of the plurality of (e.g., M) regulators 132a, 132b, 132c, and 132m may be implemented as the same type. For example, all of the plurality of (e.g. M) regulators 132a, 132b, 132c, and 132m may be implemented as the same type, or at least a part of the regulators may be implemented as different types. The plurality of (e.g., M) regulators 132a, 132b, 132c, and 132m may be connected to a switching circuit 133.

The switching circuit 133 according to various embodiments may selectively connect each of the plurality of (e.g., M) regulators (132a, 132b, 132c, 132m) to at least a part of the plurality of (e.g. N) ports 134a, 134b, 134c, and 134n. For example, one (e.g., the first regulator 132a) of the plurality of (e.g., M) regulators 132a, 132b, 132c, and 132m may be connected to one or more of the plurality of (e.g., N) ports 134a, 134b, 134c, 134n through the switching circuit 133. The switching circuit 133 may include a plurality of switches to connect each of the plurality of (e.g., M) regulators 132a, 132b, 132c, and 132m to at least one of the plurality of (e.g. N) ports 134a, 134b, 134c, and 134n. Each of the plurality of switches included in the switching circuit 133 may be controlled to an on state or an off state, for example, based on a control signal from the MCU 131. Each of the plurality of switches may be implemented, for example, as any of various types of metal oxide semiconductor field effect transistors (MOSFETs). As a voltage applied to a gate is adjusted, the state of each switch may be controlled. Herein, an operation of applying a specific voltage to the gate to control the switch to be in the on state may be performed by the electronic device 101 (e.g., the MCU 131). Alternatively, when the specific voltage is not applied to the gate, it may also be said that the switching circuit 133 is controlled by the electronic device 101 (e.g., the MCU 131).

According to various embodiments, the MCU 131 may output a control signal for the switching circuit 133 based on information received from the processor 120. The MCU 131 may receive data from the processor 120 or transmit data to the processor 120 based on various inter-chip interfaces such as serial peripheral interface (SPI), inter-IC (I2C), general-purpose input/output (GPIO), universal asynchronous receiver/transmitter (UART), ADC, and the like. The transmission interface is not limited to any particular type. The MCU 131 may be implemented as a chip capable of processing received information and outputting a switch control signal, not limited to any particular chip type. Depending on implementation, when the processor 120 is configured as an AP, the MCU 131 may be configured as, but not limited to, a chip having a lower computing capability than the AP. The MCU 131 may select a regulator to be operated, based on information received from the processor 120 (e.g., state information about the electronic device 101 and/or information associated with driving (or power consumption) of at least one load). When the MCU 131 receives the state information about the electronic device 101, the MCU 131 may identify information associated with the driving (or power consumption) of a load corresponding to the state information. For example, the MCU 131 may identify information indicating the relationship between a state information identifier and a current magnitude and/or a voltage magnitude for each load, or the relationship between a state information identifier, a regulator, regulator control information, and switch on/off information. The MCU 131 may provide a control signal for the switching circuit 133 based on the information associated with the driving (or power consumption) of the load. Alternatively, the MCU 131 may directly provide the control signal for the switching circuit 133 based on the state information about the electronic device 101. The MCU 131 may transmit switch on/off control information that controls the on/off states of the switches to the switching circuit 133. The state of each of the switches of the switching circuit 133 may be controlled to the on state or the off state, based on the received switch on/off control information. The switch on/off control information may be directly transmitted to the switches. Alternatively, the switching circuit 133 may include an element for generating a control signal. In this case, the element for generating a control signal may use the switch on/off control information to generate and transmit a control signal for controlling the state of at least one of the switches.

More specifically, the processor 120 may select at least one load to be driven from among the plurality of (e.g., N) loads 140a, 140b, 140c, and 140n. As described before, the processor 120 may determine an operation to be performed based on data received through the input device, sensing data, and/or data received through communication, and select at least the load based on the operation to be performed. For example, when the processor 120 determines to perform an operation of moving the electronic device 101 from a current position to another position, the processor 120 may transmit state information about the electronic device 101 corresponding to the operation, and/or information about an operating condition of a driving device to the MCU 131. The MCU 131 may select a load (e.g., a motor) to be driven from among the plurality of (e.g., N) loads 140a, 140b, 140c, and 140n based on the received information. Alternatively, when the processor 120 determines to perform a voice output operation, the processor 120 may select a speaker from among the plurality of (e.g., N) loads 140a, 140b, 140c, and 140n. In various embodiments, the processor 120 may determine to perform a plurality of operations simultaneously. In this case, the processor 120 may select a plurality of loads. Alternatively, the processor 120 may also select a plurality of loads even when performing one operation.

According to various embodiments, the processor 120 may transmit information related to at least one selected load to the MCU 131. The processor 120 may transmit information about the selected load and its operating condition (e.g., the magnitude of a voltage and/or the magnitude of a current) to the MCU 131 or transmit state information about the electronic device 101 to the MCU 131. The MCU 131 may select at least one regulator to be driven based on the received information. For example, the MCU 131 may select at least one regulator to be driven based on the magnitude of a current required for the at least one selected load. As described later in more detail, the efficiency of a regulator may be changed according to the magnitude of the output current of the regulator. For example, when the output current of a specific regulator is of a first magnitude, the regulator may have a first efficiency, and when the output current of the regulator is of a second magnitude, the regulator may have a second efficiency. The first efficiency may be relatively high, which may refer, for example, to when the specific regulator outputs an output current of the first magnitude, the regulator operates with a relatively high efficiency. The MCU 131 may select a regulator based on at least one selected load so that the efficiency of the driven regulator is maximized. When it is said that the efficiency of the driven regulator is maximized, this may refer, for example, to the overall efficiency of the selected regulator being higher than the efficiencies of other selection combinations. When it is determined that the first load 140a is to be operated, the first load 140a may require a current of the second magnitude. The MCU 131 may control driving two regulators such that each of the regulators outputs a current of the first magnitude, instead of controlling driving of one regulator such that the regulator outputs a current of the second magnitude. In this case, the overall efficiency of the two regulators may be higher than that of the single regulator. Various examples will be described later in more detail. The MCU 131 may control the switching circuit 133 to connect the at least one selected regulator to the load.

As described before, at least a part of the plurality of regulators 132a, 132b, 132c, and 132m may be connected to at least a part of the plurality of ports 134a, 134b, 134c, and 134n, and the connections may be changed based on a control signal from the MCU 131. The MCU 131 may determine a connection offering an optimal efficiency based on an operating load and an operating condition of the load. Each of the plurality of ports 134a, 134b, 134c, and 134n may be connected to the plurality of loads 140a, 140b, 140c, and 140n. The plurality of ports 134a, 134b, 134c, and 134n may be a structure configured to connect the PMU 202 to the plurality of loads 140a, 140b, 140c, 140n, but may be omitted depending on implementation. As described before, the MCU 131 may perform a computation related to power supply, and the processor 120 may perform a computation for an actual operation. Therefore, computations may be dualized.

According to various embodiments, each of the plurality of loads 140a, 140b, 140c, and 140n may refer to a component or a set of components of the electronic device 101 consuming power. For example, when the electronic device 101 is implemented as a robot, the loads may include, but not be limited to, a processor, a memory, a communication circuit, a display for displaying a screen, a speaker for outputting a voice, a microphone for obtaining a voice, and a sensor. A load may also be referred to as hardware, a client, a peripheral device, a power consuming element, or an element. Although a load may refer to one component of the electronic device 101, the load may also refer to a set of a plurality of components. For example, when the electronic device 101 is implemented as a humanoid robot, the first load 140a may be a display included in the head unit, an actuator for driving the head unit, or a part of the head unit including a speaker included in the head unit, as well as a display.

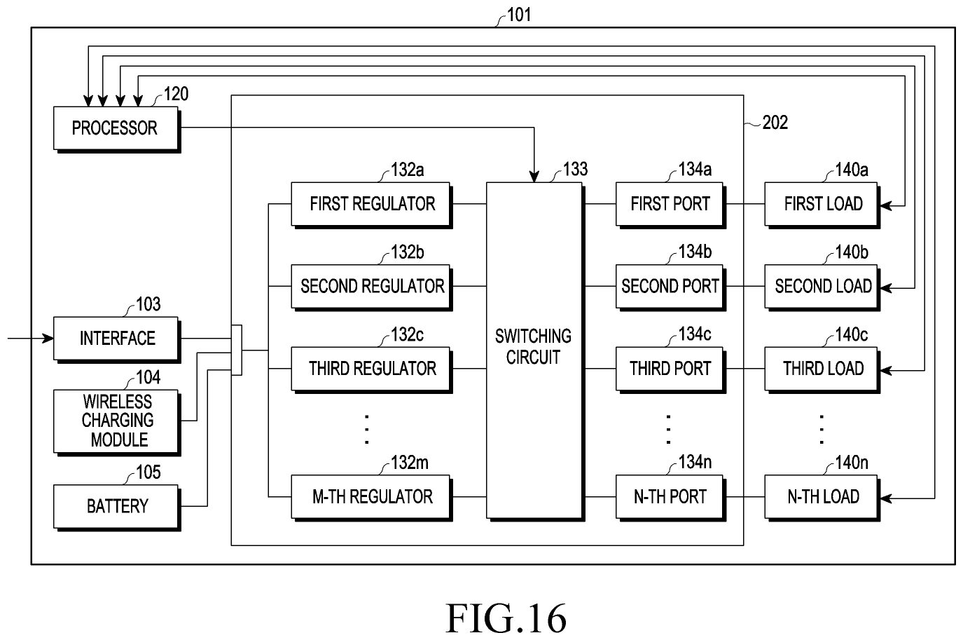

FIG. 16 is a block diagram illustrating an example electronic device according to various embodiments.

In the electronic device 101 (e.g., the first electronic device 200 in FIG. 2) according to the embodiment of FIG. 16, the PMU 202 may not include the MCU 131, compared to the PMU 202 illustrated in FIG. 15. The processor 120 outside the PMU 202 according to various embodiments may determine on/off control information for the switches of the switching circuit 133. As described before, the processor 120 may determine an operation of the electronic device 101, and determine at least one load and its operating condition corresponding to the determined operation of the electronic device 101. The processor 120 may determine at least one regulator to be connected to the at least one load based on the at least one load and its operating condition. The processor 120 may determine on/off states for the switches of the switching circuits 133, which may connect the determined regulator to the at least one load. The processor 120 may transmit switch on/off control information to the PMU 202, to control the on/off states of the switches. The state of each switch in the PMU 202 may be controlled to the on state or the off state based on the received switch on/off control information. The switch on/off information may be transmitted directly to the switches. Alternatively, the switching circuit 133 may include an element for generating a control signal. In this case, the element for generating a control signal may generate a control signal to control the state of at least one of the switches based on the switch on/off control information and transmit the generated control signal.

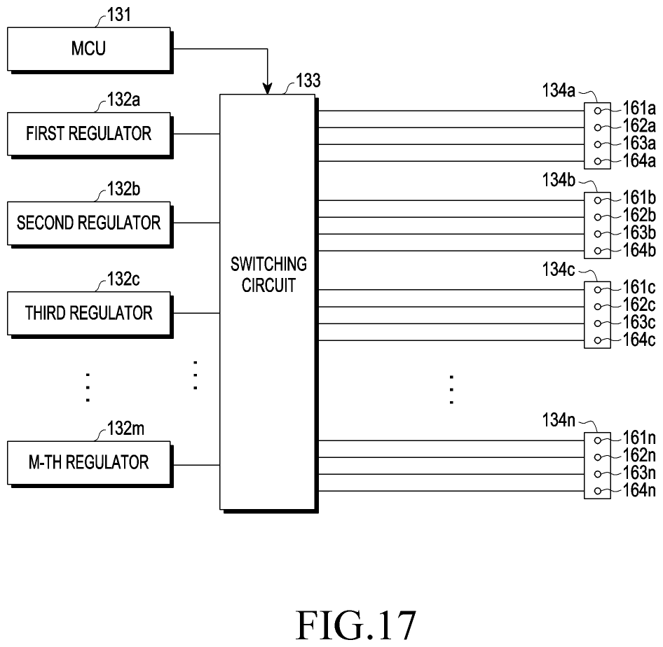

FIG. 17 is a diagram illustrating an example PMU according to various embodiments.

According to various embodiments, each of the plurality of ports 134a, 134b, 134c, and 134n of the PMU 202 may include a plurality of sub-ports 161a, 162a, 163a, and 164a, 161b, 162b, 163b, and 164b, 161c, 162c, 163c, and 164c, or 161n, 162n, 163n, and 164n. The sub-ports 161a, 162a, 163a, and 164a may be configured to output different voltages, respectively, which should not be construed as limiting. In the first port 134a, for example, the first sub-port 161a may be configured to output 12V, the second sub-port 162a may be configured to output 5V, and the third sub-port 163a may be configured to output 3.3V. In various embodiments, the first load 140a may require power of two or more voltages (e.g., 12V, 5V, and 3.3V). In this case, the first load 140a may be connected to the first sub-port 161a, the second sub-port 162a, and the third sub-port 163a to receive processed power from the first regulator 132a, the second regulator 132b, and the third regulator 132c, respectively. The second load 140b may require power of a single voltage of 12V, for example. The second load 140b may be connected to, for example, the first sub-port 161a and the fifth sub-port 161b to receive power from the first regulator 132a and the fourth regulator 132d. The third load 140c may require power of a single voltage of 12V, for example. The third load 140c may be connected to, for example, the ninth sub-port 161c to receive power from the fifth regulator 132e.

FIG. 18 is a block diagram illustrating an example PMU according to various embodiments. Referring to FIG. 18, the PMU 202 may supply power to a plurality of modules or circuits 1860 included in the first electronic device 200, or may supply power to a plurality of modules 1820 (e.g., the second electronic devices 300) detachably engaged with the first electronic device 200.

According to various embodiments, the PMU 202 may include the MCU 131. The MCU 131 may include a GPIO interface and generate a pulse width modulation (PWM) signal or a pulse frequency modulation (PFM) signal. Further, the MCU 131 may include over voltage protection (OVP)/over current protection (OCP) and over temperature protection (OTP) functions, and receive a V/I sensing signal. Further, the MCU 131 may provide an SPI, I2C, or UART interface.

An input power management/charging module 1813 according to various embodiments may be connected wiredly to an external power source 1840 to transfer power from the external power source 1840 to the PMU 202. The input power management/charging module 1813 may be implemented as, for example, a connector for connecting a cable for power supply, or as a cable for power supply and a connector for connecting the cable to the external power source. The input power management/charging module 1813 may be implemented as, but not limited to, any of various USB types of connectors. When receiving DC power from the external power source, the input power management/charging module 1813 may transmit the received DC power to the PMU 202 with or without conversion of the magnitude of the voltage of the DC power. When receiving AC power from the external power source, the input power management/charging module 1813 may convert the AC power to DC power and/or convert the magnitude of the voltage of the AC power and transmit the converted power to the PMU 202.

According to various embodiments, a first wireless power receiver 1812 may receive wireless power from a wireless charging transmitter 1830. The first wireless power receiver 1812 may be implemented in the scheme defined in the WPC standard (or Qi standard) or the A4WP standard (or AFA standard). A battery 1850 according to various embodiments may be implemented as a rechargeable secondary battery. The battery 1850 may be charged with, for example, power received through the input power management/charging module 1813 and/or power received through the first wireless power receiver 1812. The battery 1850 may also transfer stored power to the PMU 202. Power from the input power management/charging module 1813 and/or power from the first wireless power receiver 1812 may be transferred to the battery 1850 and/or to the PMU 202.

The MCU 131 may receive power from the external power source 1840 or the battery 1850, and transmit wireless power to the plurality of modules 1820 (e.g., a head rotation module, a hand rotation module, a leg rotation module, and an accessory module) engaged with the first electronic device 200 through L wireless power transmitters 1811 (e.g., the first wireless power transceivers 204). Each of the plurality of modules 1820 may receive wireless power through a corresponding wireless power receiver among L wireless power receivers (e.g., the second wireless power transceivers 304). According to various embodiments, each of the first to L^{th} wireless power receivers may correspond to the second wireless power transceiver 304 of FIG. 2, and may be implemented as a module capable of conducting non-contact data communication and supplying power, as illustrated in FIG. 3.

According to various embodiments, the PMU 202 may supply power to N modules among the modules 1860 configured inside the first electronic device 200 through N buck converters 1814. The N buck converters 1814 may be step-down DC/DC converters capable of power setting or conversion by a program. For example, by the program, a first buck converter may output power of 3.3V to 5.0V for use in data transmission and reception between circuits included in the first electronic device 200, a second buck converter may output power of 5V to 12V to drive the sensor module, and an N^{th} buck converter may output power of 12 to 28V to control a motion of the first electronic device 200. According to various embodiments, the MCU 131 may change a DC/DC feedback resistance or control a PWM signal according to required power for each module, to output power of a corresponding voltage through each buck converter 1814.

According to various embodiments, the MCU 131 may supply wireless power to a head module through a modular wireless power transmitter 1815. The MCU 131 may supply the power through M boost converters 1816 corresponding to M modules among the modules 1860 configured inside the first electronic device 200. The M boost converters 1816 may be step-up DC/DC converters capable of power setting or conversion by a program. For example, by the program, a first boost converter may output power of 24V to 36V to supply power to a display module included in the first electronic device 200, and an N^{th} boost converter may supply power of 24 to 48V to control a motion of a manipulator module.

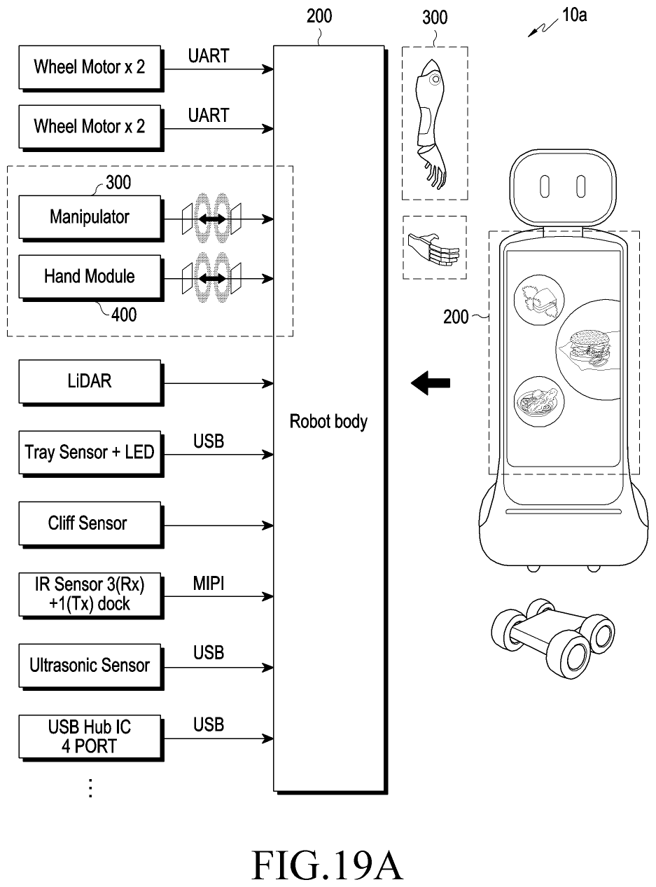

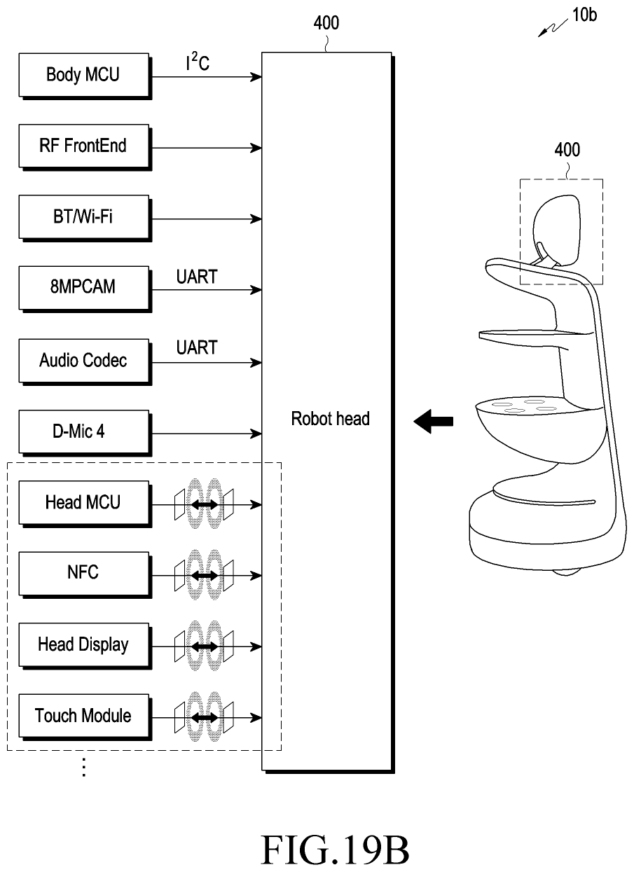

FIG. 19A is a diagram illustrating example connection relationships of a robot body according to various embodiments. Referring to FIG. 19A, a robot body (e.g., the first electronic device or the body unit) 200 included in a robot 10a may be connected to various modules or circuits to supply power or transmit and receive data.

According to various embodiments, the robot body 200 may communicate with a plurality of wheel motors via a UART interface and with a plurality of header motors via a UART interface. The robot body 200 may wirelessly transmit power to and receive power from a manipulator 300, and may wirelessly transmit power to and receive power from a hand module.

The robot body 200 may receive sensed signals from various sensors (e.g., a light detection and ranging (LiDAR) sensor, a tray sensor, a light emitting diode (LED), a cliff sensor, an infrared (IR) sensor, and an ultrasonic sensor) via various interfaces (e.g., USB and mobile industry processor interface (MIPI)). The robot body 200 may communicate with a USB hub IC via a USB interface.

FIG. 19B is a diagram illustrating connection relationships of a robot head according to various embodiments. Referring to 19B, a robot head (e.g., a second electronic device or a device) 400 included in a robot 10b may be connected to various modules or circuits to supply power or transmit and receive data.

According to various embodiments, the robot head 400 may communicate with an MCU of a robot body via an I2C communication interface. The robot head 400 may communicate with an RF front-end module, and with a short-range communication module (e.g., Bluetooth (BT)/wireless fidelity (Wi-Fi) module). The robot head 400 may receive an 8MPCAM or audio codec signal via a UART interface, and may receive a D-Mic 4 signal.

The robot head 400 may wirelessly transmit power to and receive power from various modules (e.g., a robot head MCU, an NFC module, a head display, and a touch module).

Various embodiments of a first waveguide (e.g., the first waveguide 230 of FIG. 3) and a second waveguide (e.g., the second waveguide 330 of FIG. 3) will be described below with reference to FIGS. 20A to 23E.

Example embodiments of the first waveguide 2002 and the second waveguide 2003 in which the first recesses 2020 and 2030 are formed may be disclosed through FIGS. 20A to 20E.

FIG. 20A is a cross-sectional side view illustrating an example of a first waveguide and a cross section of a second waveguide in which first recesses are formed according to an embodiment of the disclosure. A first waveguide 2002 illustrated in FIGS. 20A to 20E may correspond to the first waveguides 230, 230b and 230c illustrated in FIGS. 7A to 8D. A second waveguide 2003 may also correspond to the second waveguides 330, 330b, and 330c illustrated in FIGS. 7A to 8D. Accordingly, the first waveguide 2002 and the second waveguide 2003 may be supported by a first housing (e.g., the first housing 210 in FIG. 3) and a second housing (e.g., the second housing 310 in FIG. 3), respectively. The first waveguide 2002 and the second waveguide 2003 may be aligned along a first rotation axis X, apart from each other by a predetermined distance (e.g., 0.5 mm to 1 mm) in a non-contact connection structure. The first waveguide 2002 and the second waveguide 2003 illustrated in FIGS. 20A to 20D may have an EBG-based separate waveguide structure. The first waveguide 2002 and the second waveguide 2003 may include recesses formed in a predetermined width aa and a predetermined depth cc, so that an electronic device (e.g., the robot 10 in FIG. 1 or the electronic devices 200 and 300 in FIG. 2) may conduct data communication with designed frequency characteristics within a specific frequency range.

FIG. 20A is a side view illustrating a cross section of the first waveguide 2002 and a cross section of the second waveguide 2003 according to an embodiment. First recesses 2020 and 2030 of the first width aa and the first depth cc may be formed into one surface 2002a of the first waveguide 2002 and one surface 2003a of the second waveguide 2003, respectively. While not shown, a (1-1)^{th} recess 2021 of the first waveguide 2002 shown on the left side of the axis X and a (1-2)^{th} recess 2022 of the first waveguide 2002 on the right side of the axis X may be connected to each other to form the single recess 2020 in FIG. 20A. According to an embodiment, the (1-1)^{th} recess 2021 and the (1-2)^{th} recess 2022 may form a ring-shaped recess (e.g., the recess 233 in FIG. 8A), when the surface 2002a of the first waveguide 2002 is viewed from a direction parallel to the axis X. According to an embodiment, as the surface 2002a of the first waveguide 2002 and the surface 2003a of the second waveguide 2003 oppose each other, the first recess 2020 formed on the surface 2002a of the first waveguide 2002 and the first recess 2030 formed on the surface 2003a of the second waveguide 2003 may be formed at positions corresponding to each other. A (2-1)^{th} recess 2031 of the second waveguide 2003 on the left side of the axis X and a (2-2)^{th} recess 2032 of the second waveguide 2003 on the right side of the axis X may also be connected to each other in FIG. 20A. According to an embodiment, when the surface 2003a of the second waveguide 2003 is viewed from a direction parallel to the axis X, the (2-1)^{th} recess 2031 and the (2-2)^{th} recess 2032 may form a ring-shaped recess (e.g., the recess 333 in FIG. 8A).

FIG. 20B is a cross-sectional side view illustrating an example of a first waveguide and a cross section of a second waveguide in which first recesses are formed according to a different embodiment from the embodiment illustrated in FIG. 20A. FIG. 20C is a cross-sectional side view illustrating an example of a first waveguide and a cross section of a second waveguide in which first recesses are formed according to an embodiment different from the embodiments of FIGS. 20A and 20B.

The first recess 2030 is shown as formed only on the surface 2003a of the second waveguide 2003 in FIG. 20B. The first recess 2020 is shown as formed only on the surface 2002a of the first waveguide 2002 in FIG. 20C. In each of the embodiments of FIGS. 20B and 20C, the first recess 2020 may be ring-shaped.

In the above-described embodiments of FIGS. 20A to 20C, the first recesses 2020 and 2030 may form a recess in a closed loop shape.

FIG. 20D is a cross-sectional diagram illustrating an example of a first waveguide and a cross section of a second waveguide according to a different embodiment from the embodiments of FIGS. 20A, 20B, and 20C. In FIG. 20D, first recesses 2021 and 2032 may be formed on the surface 2002a of the first waveguide 2002 and the surface 2003a of the second waveguide 2003, respectively. The first recess 2021 formed in the first waveguide 2002 and the first recess 2032 formed in the second waveguide 2003 may be arc-shaped or ring-shaped (e.g., the recesses 233 and 333 in FIG. 8B or 8C). According to an embodiment, the first recess 2021 formed on the first waveguide 2002 and the first recess 2032 formed on the second waveguide 2003 may be formed at positions symmetrical with respect to a virtual point P in a space between the first waveguide 2022 and the second waveguide 2003, without facing each other.

FIG. 20E is a cross-sectional diagram illustrating an example of a first waveguide and a cross section of a second waveguide in which first recesses are formed according to a different embodiment from the embodiments of FIGS. 20A, 20B, 20C, and 20D. In FIG. 20E, first recesses 2021 and 2031 may be formed on the surface 2002a of the first waveguide 2002 and the surface 2003a of the second waveguide 2003, respectively. The first recess 2021 formed on the first waveguide 2002 and the first recess 2031 formed on the second waveguide 2003 may be arc-shaped or ring-shaped (e.g., the recesses 233 and 333 in FIG. 8D). According to an embodiment, the first recess 2021 on the first waveguide 2002 and the first recess 2031 on the second waveguide 2003 may be formed at symmetrical positions with respect to a virtual plane Y perpendicular to the axis X, facing each other.

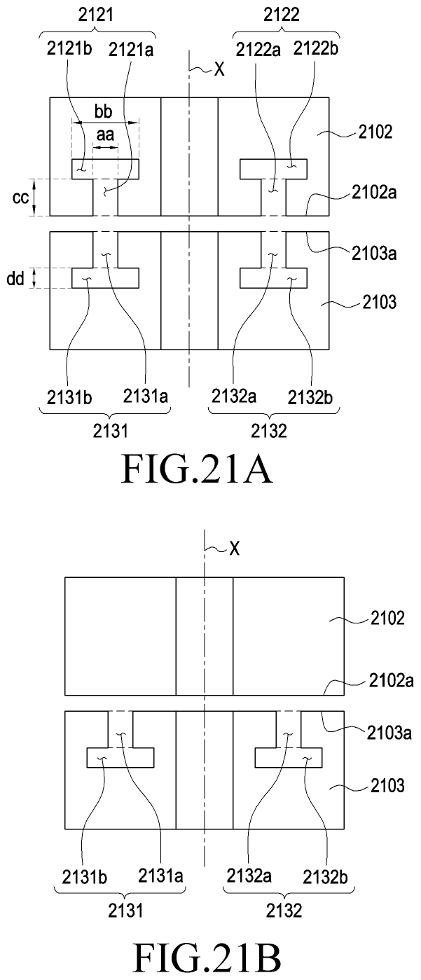

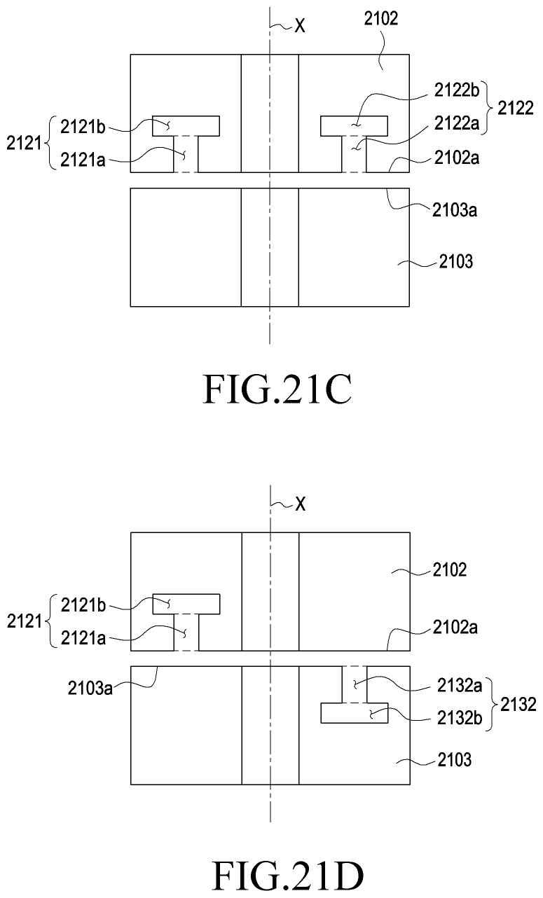

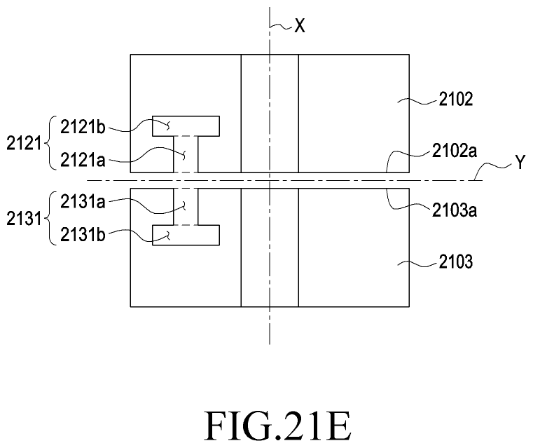

FIG. 21A is a cross-sectional side view illustrating an example of a first waveguide and a second waveguide in which first and second recesses are formed according to an embodiment of the disclosure. FIG. 21B is a cross-sectional side view illustrating an example of a first waveguide and a second waveguide in which first and second recesses are formed according to an embodiment different from the embodiment of FIG. 21A. FIG. 21C is a cross-sectional side view illustrating examples of a first waveguide and a second waveguide in which first and second recesses are formed according to an embodiment different from the embodiments of FIGS. 21A and 21B. FIG. 21D is a side view illustrating cross sections of a first waveguide and a second waveguide in which first and second recesses are formed according to an embodiment different from the embodiments of FIGS. 21A, 21B, and 21C. FIG. 21E is a side view illustrating cross sections of a first waveguide and a second waveguide in which first and second recesses are formed according to a different embodiment from the embodiments of FIGS. 21A, 21B, 21C, and 21D.

Through FIGS. 21A to 21E, embodiments of a first waveguide 2102 in which a first recess 2131a and 2132a and a second recess 2121b and 2122b are formed and a second waveguide 2103 in which a first recess 2131a and 2132a and a second recess 2121b and 2122b are formed may be disclosed.

In describing the embodiments of FIGS. 21A to 21E, a description redundant with the description of the embodiments of FIGS. 20A to 20E will be avoided.

The first waveguide 2102 and the second waveguide 2103 may include the first recess 2121a and 2122a and the first recess 2131a and 2132a formed in a first width aa and a first depth cc and the second recess 2131b and 2132b and the second recess 2131b and 2132b formed in a second width bb and a second depth dd. The first recess 2121a and 2122a and the first recess 2131a and 2132a may be formed, respectively on one surface 2102a of the first waveguide 2102 and one surface of 2103a the second waveguide 2103.

The second recess 2131b and 2132b and the second recess 2131b and 2132b may be recessed further inward from the first recess 2121a and 2122a and the first recess 2131a and 2132a.

The first recess 2121a and 2122a, the first recess 2131a and 2132a, the second recess 2131b and 2132b, and the second recess 2131b and 2132b may be formed in various dimensions. Further, various combinations may be available as in the various embodiments illustrated in FIGS. 21A to 21E.

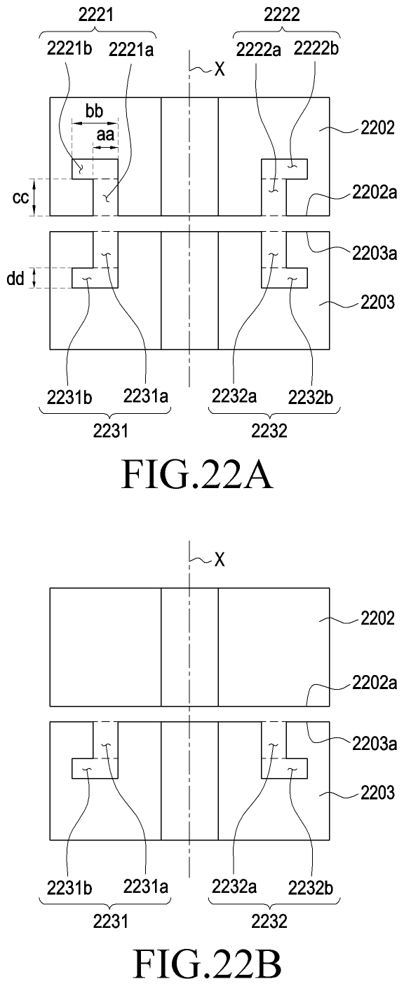

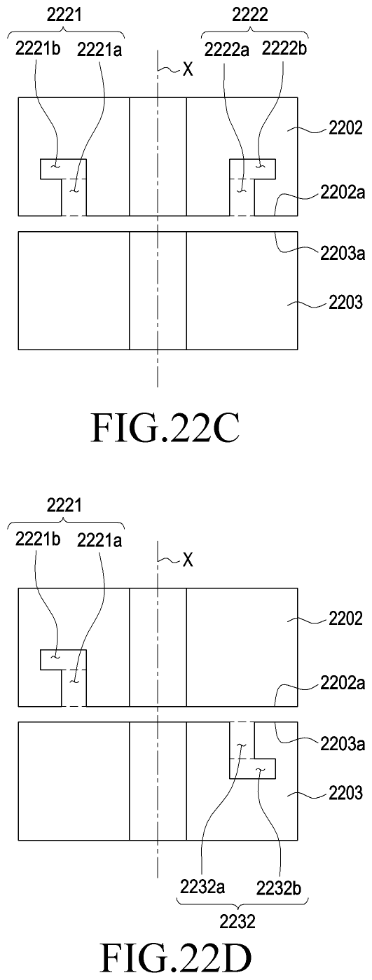

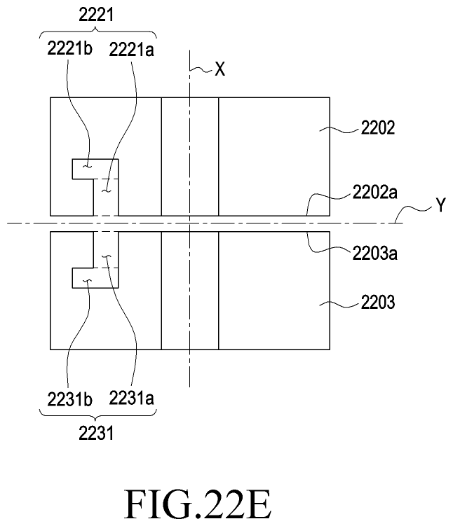

FIG. 22A is a cross-sectional side view illustrating examples of a first waveguide and a second waveguide in which first and third recesses are formed according to an embodiment of the disclosure. FIG. 22B is a cross-sectional side view illustrating examples of a first waveguide and a second waveguide in which first and third recesses are formed according to an embodiment different from the embodiment of FIG. 22A. FIG. 22C is a cross-sectional side view illustrating examples of a first waveguide and a second waveguide in which first and third recesses are formed according to a different embodiment from the embodiments of FIGS. 22A and 22B. FIG. 22D is a cross-sectional side view illustrating examples of a first waveguide and a second waveguide in which first and third recesses are formed according to a different embodiment from the embodiments of FIGS. 22A, 22B, and 22C. FIG. 22E is a cross-sectional side view illustrating examples of a first waveguide and a second waveguide in which first and third recesses are formed according to a different embodiment from the embodiments of FIGS. 22A, 22B, 22C, and 22D.

Through FIGS. 22A to 22E, embodiments of a first waveguide 2202 with a first recess 2221a and 2222a and a third recess 2221b and 2222b formed thereon and a second waveguide 2203 with a first recess 2231a and 2232a and a third recess 2231b and 2232b formed thereon may be disclosed.

In describing the embodiments of FIGS. 22A to 22E, a description redundant with the description of FIGS. 20A to 20E will be avoided.

The first waveguide 2202 and the second waveguide 2203 may include the first recess 2221a and 2222a and the first recess 2231a and 2232a formed in a first width aa and a first depth cc, and the third recess 2231b and 2232b and the third recess 2231b and 2232b formed in a second width bb and a second depth dd. The first recess 2221a and 2222a and the first recess 2231a and 2232a may be formed on one surface 2202a of the first waveguide 2202 and one surface a2203a of the second waveguide 2203. The third recess 2223b and 2232b and the third recess 2231b and 2232b may be recessed further inward from the first recess 2221a and 2222a and the first recess 2231a and 2232a.

The first recess 2221a and 2222a, the first recess 2231a and 2232a, the third recess 2223b and 2232b, and the third recess 2231b and 2232b may also be formed in various dimensions. While the third recess 2223b and 2232b and the third recess 2231b and 2232b are shown as extended in a direction away from the axis X in the embodiment shown in FIGS. 21A to 21E, the third recess 2223b and 2232b and the third recess 2231b and 2232b may be extended in a direction closer to the axis X. Further, various combinations may be available as in the various embodiments illustrated in FIGS. 22A to 22E.

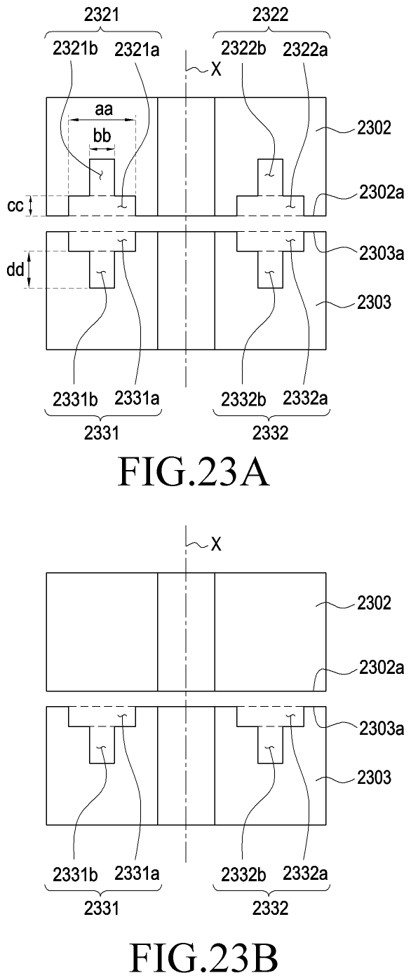

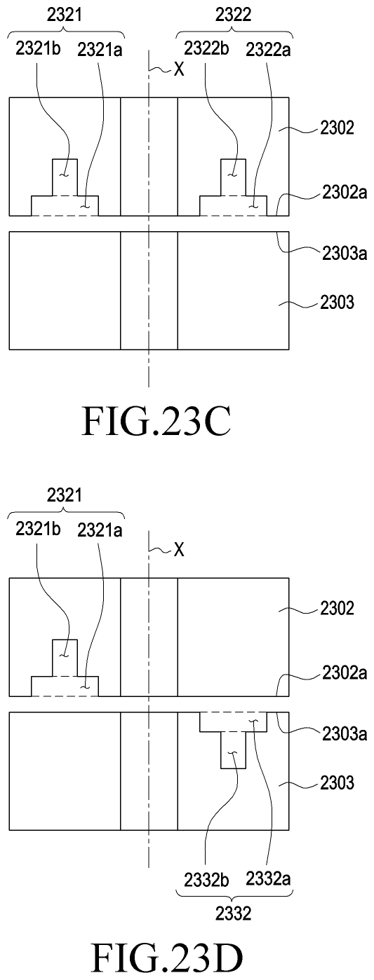

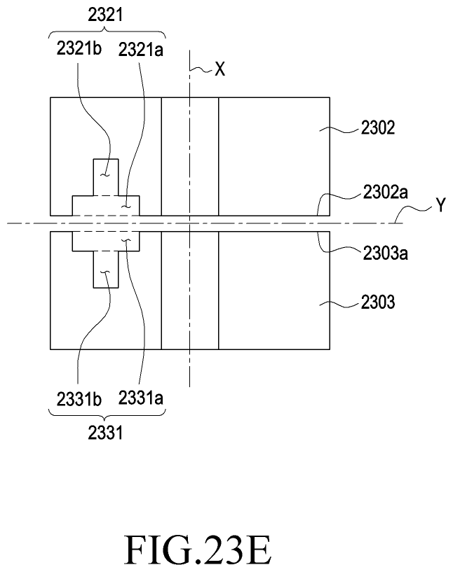

FIG. 23A is a cross-sectional side view illustrating examples of a first waveguide and a second waveguide in which fourth and fifth recesses are formed according to an embodiment of the disclosure. FIG. 23B is a cross-sectional side view illustrating examples of a first waveguide and a second waveguide in which fourth and fifth recesses are formed according to an embodiment from the embodiment of FIG. 23A. FIG. 23C is a cross-sectional side view illustrating examples of a first waveguide and a second waveguide in which fourth and fifth recesses are formed according to a different embodiment from the embodiments of FIGS. 23A and 23B. FIG. 23D is a cross-sectional side view illustrating examples of a first waveguide and a second waveguide in which fourth and fifth recesses are formed according to a different embodiment from the embodiments of FIGS. 23A, 23B, and 23C. FIG. 23E is a cross-sectional side view illustrating examples of a first waveguide and a second waveguide in which fourth and fifth recesses are formed according to a different embodiment from the embodiments of FIGS. 23A, 23B, 23C, and 23D.

Through FIGS. 23A to 23E, embodiments of a first waveguide 2302 with a fourth recess 2331a and 2332a and a fifth recess 2321b and 2322b formed thereon and a second waveguide 2303 with a fourth recess 2331a and 2332a and a fifth recess 2321b and 2322b formed thereon may be disclosed.

In describing the embodiments of FIGS. 23A to 23E, a description redundant with the description of the embodiments of FIGS. 20A to 20E will be avoided.

The first waveguide 2302 and the second waveguide 2303 may include the fourth recess 2321a and 2322a and the fourth recess 2331a and 2332a formed in a first width aa and a first depth cc, and the fifth recess 2331b and 2332b and the fifth recess 2331b and 2332b formed in a second width bb and a second depth dd. The fourth recess 2321a and 2322a and the fourth recess 2331a and 2332a may be formed on one surface 2302a of the first waveguide 2302 and one surface 2303a of the second waveguide 2303, respectively. The fifth recess 2331b and 2332b and the fifth recess 2331b and 2332b may be recessed further inward from the fourth recess 2321a and 2322a and the fourth recess 2331a and 2332a. Unlike the previous embodiment, in the present embodiment, the first width aa of the fourth recess 2321a and 2322a and the fourth recess 2331a and 2332a may be larger than the second width bb of the fifth recess 2331b and 2332b and the fifth recess 2331b and 2332b.

The fourth recess 2321a and 2322a, the fourth recess 2331a and 2332a, the fifth recess 2331b and 2332b, and the fifth recess 2331b and 2332b may be formed in various dimensions. Further, various combinations may be available like the various embodiments shown in FIGS. 23A to 23E.

Various embodiments of a first waveguide and a second waveguide in which recesses are formed for impedance matching have been described above. Many other types of recesses (and/or protrusions (e.g., the protrusions in FIG. 7F)) may be applied.

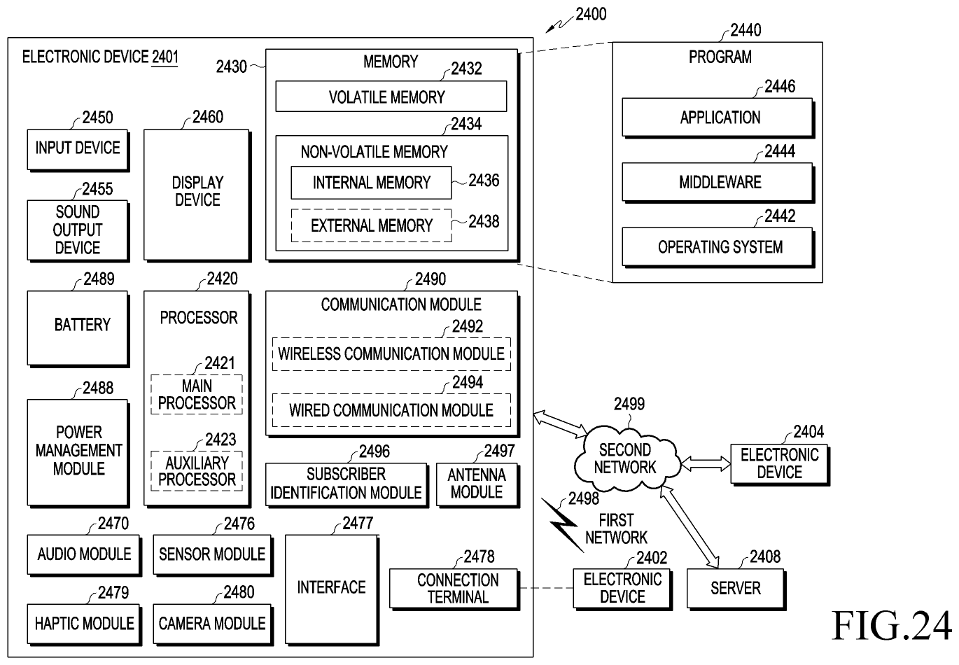

FIG. 24 is a block diagram illustrating an example electronic device 101 (e.g., the robot 10 of FIG. 1 or the first electronic device 200 or the second electronic devices 300 and 400 of FIG. 2) in a network environment 2400 according to various embodiments. Referring to FIG. 24, the electronic device 101 in the network environment 2400 may communicate with an electronic device 2402 via a first network 2498 (e.g., a short-range wireless communication network), or an electronic device 2404 or a server 2408 via a second network 2499 (e.g., a long-range wireless communication network). According to an embodiment, the electronic device 2401 may communicate with the electronic device 2404 via the server 2408. According to an embodiment, the electronic device 2401 may include a processor 2420, a memory 2430, an input device 2450, a sound output device 2455, a display device 2460, an audio module 2470, a sensor module 2476, an interface 2477, a haptic module 2479, a camera module 2480, a power management module 2488, a battery 2489, a communication module 2490, a subscriber identification module (SIM) 2496, and an antenna module 2497. In some embodiments, at least one (e.g., the display device 2460 or the camera module 2480) of the components may be omitted from the electronic device 101, or one or more other components may be added in the electronic device 101. In some embodiments, some of the components may be implemented as single integrated circuitry. For example, the sensor module 2476 (e.g., a fingerprint sensor, an iris sensor, or an illuminance sensor) may be implemented as embedded in the display device 2460.

The processor 2420 may execute, for example, software (e.g., a program 2440) to control at least one other component (e.g., a hardware or software component) of the electronic device 101 connected to the processor 2420, and may perform various data processes and computations. The processor 2420 may load a command or data received from another component (e.g., the sensor module 2476 or the communication module 2490) in volatile memory 2432, process the command or the data stored in the volatile memory 2432, and store resulting data in non-volatile memory 2434. According to an embodiment, the processor 2420 may include a main processor 2421 (e.g., a CPU or an AP), and an auxiliary processor 2423 (e.g., a graphics processing unit (GPU), an image signal processor (ISP), a sensor hub processor, or a communication processor (CP)) that is operable independently from, or in conjunction with, the main processor 2421. Additionally or alternatively, the auxiliary processor 2423 may be adapted to consume less power than the main processor 2421, or to be specific to a specified function. The auxiliary processor 2423 may be implemented as separate from, or as part of the main processor 2421.

The auxiliary processor 2423 may control at least some of functions or states related to at least one component (e.g., the display device 2460, the sensor module 2476, or the communication module 2490) among the components of the electronic device 101, instead of the main processor 2421 while the main processor 2421 is in an inactive (e.g., sleep) state, or together with the main processor 2421 while the main processor 2421 is in an active state (e.g., executing an application). According to an embodiment, the auxiliary processor 2423 (e.g., an ISP or a CP) may be implemented as part of another component (e.g., the camera module 2480 or the communication module 2490) functionally related to the auxiliary processor 2423. The memory 2430 may store various data used by at least one component (e.g., the processor 2420 or the sensor module 2476) of the electronic device 101. The various data may include, for example, software (e.g., the program 2440) and input data or output data for a command related thereto. The memory 2430 may include the volatile memory 2432 or the non-volatile memory 2434.

The program 2440 may be stored in the memory 2430 as software, and may include, for example, an operating system (OS) 2442, middleware 2444, or an application 2446.

The input device 2450 may receive a command or data to be used by other component (e.g., the processor 2420) of the electronic device 2401, from the outside (e.g., a user) of the electronic device 2401. The input device 2450 may include, for example, a microphone, a mouse, or a keyboard.

The sound output device 2455 may output sound signals to the outside of the electronic device 101. The sound output device 2455 may include, for example, a speaker or a receiver. The speaker may be used for general purposes, such as playing multimedia or playing record, and the receiver may be used only for incoming calls. According to an embodiment, the receiver may be implemented as separate from, or as part of the speaker.

The display device 2460 may visually provide information to a user of the electronic device 101. The display device 2460 may include, for example, a display, a hologram device, or a projector and control circuitry to control a corresponding one of the display, hologram device, and projector. According to an embodiment, the display device 2460 may include touch circuitry adapted to detect a touch, or a pressure sensor adapted to measure the intensity of force incurred by the touch.

The audio module 2470 may convert a sound into an electrical signal and vice versa. According to an embodiment, the audio module 2470 may obtain the sound via the input device 2450, or output the sound via the sound output device 2455 or a headphone of an external electronic device (e.g., an electronic device 2402 such as a speaker or a headphone) wiredly or wirelessly engaged with the electronic device 101.

The sensor module 2476 may detect an operational state (e.g., power or temperature) of the electronic device 101 or an environmental state external to the electronic device 2401, and then generate an electrical signal or data value corresponding to the detected state. According to an embodiment, the sensor module 2476 may include, for example, a gesture sensor, a gyro sensor, an atmospheric pressure sensor, a magnetic sensor, an acceleration sensor, a grip sensor, a proximity sensor, a color sensor, an IR sensor, a biometric sensor, a temperature sensor, a humidity sensor, or an illuminance sensor.

The interface 2477 may support one or more specified protocols to be used for the electronic device 101 to be connected to the external electronic device (e.g., the electronic device 2402) wiredly or wirelessly. According to an embodiment, the interface 2477 may include, for example, a high definition multimedia interface (HDMI), a USB interface, a secure digital (SD) card interface, or an audio interface.

A connecting terminal 2478 may include a connector via which the electronic device 101 may be physically connected to the external electronic device (e.g., the electronic device 2402). The connecting terminal 2478 may include, for example, a HDMI connector, a USB connector, a SD card connector, or an audio connector (e.g., a headphone connector).

The haptic module 2479 may convert an electrical signal into a mechanical stimulus (e.g., a vibration or a movement) or electrical stimulus which may be recognized by a user via his tactile sensation or kinesthetic sensation. The haptic module 2479 may include, for example, a motor, a piezoelectric element, or an electric stimulator.

The camera module 2480 may capture a still image or moving images. According to an embodiment, the camera module 2480 may include one or more lenses, image sensors, ISPs, or flashes.

The power management module 2488 may manage power supplied to the electronic device 101. The power management module 2488 may be implemented as at least part of, for example, a power management integrated circuit (PMIC).

The battery 2489 may supply power to at least one component of the electronic device 101. The battery 2489 may include, for example, a primary cell which is not rechargeable, a secondary cell which is rechargeable, or a fuel cell.

The communication module 2490 may support establishing a wired communication channel or a wireless communication channel between the electronic device 101 and the external electronic device (e.g., the electronic device 2402, the electronic device 2404, or the server 2408) and performing communication via the established communication channel. The communication module 2490 may include one or more CPs that are operable independently from the processor 2420 (e.g., the AP) and supports wired communication or wireless communication. According to an embodiment, the communication module 2490 may include a wireless communication module 2492 (e.g., a cellular communication module, a short-range wireless communication module, or a global navigation satellite system (GNSS) communication module) or a wired communication module 2494 (e.g., a local area network (LAN) communication module or a power line communication (PLC) module). A corresponding one of these communication modules may communicate with the external electronic device via the first network 2498 (e.g., a short-range communication network, such as Bluetooth™, Wi-Fi direct, or infrared data association (IrDA)) or the second network 2499 (e.g., a long-range communication network, such as a cellular network, the Internet, or a computer network (e.g., LAN or wide area network (WAN)). These various types of communication modules may be implemented as a single chip, or may be implemented as multi chips separate from each other.

According to an embodiment, the wireless communication module 2492 may identify and authenticate the electronic device 101 in a communication network, using subscriber information stored in the subscriber identification module 2496.

The antenna module 2497 may include one or more antennas that transmit or receive a signal or power to or from the outside of the electronic device 101. According to an embodiment, the communication module 2490 (e.g., the wireless communication module 2492) may transmit or receive a signal to or from an external electronic device through an antenna appropriate for a communication scheme.

At least some of the above-described components may be coupled mutually and communicate signals (e.g., commands or data) therebetween via an inter-peripheral communication scheme (e.g., a bus, GPIO, SPI, or MIPI).

According to an embodiment, commands or data may be transmitted or received between the electronic device 101 and the external electronic device 2404 via the server 2408 connected to the second network 2499. Each of the electronic devices 2402 and 2404 may be a device of a same type as, or a different type, from the electronic device 101. According to an embodiment, all or some of operations to be executed at the electronic device 101 may be executed at one or more external electronic devices. According to an embodiment, if the electronic device 101 should perform a function or a service automatically or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome to provide the requested function or service. To that end, a cloud computing, distributed computing, or client-server computing technology may be used, for example.

According to various embodiments of the disclosure, because power and data are transmitted and received between electronic devices by a non-contact connection structure, not a moving power line (e.g., cable), there is no limit on a movement range (or rotation radius) which might otherwise be limited due to structural/electromagnetic interference of a power line, a rotation speed is not decreased by friction and joints, and durability may be increased.

According to various embodiments of the disclosure, power and data may be transmitted and received between electronic devices by a non-contact connection structure, not a moving power line (e.g., cable), and required power and data may be efficiently managed by a power supply device.

It should be appreciated that various embodiments of the disclosure and the terms used therein are not intended to limit the technological features set forth herein to particular embodiments and include various changes, equivalents, and/or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to “(operatively or communicatively) coupled to” or “connected to” another element (e.g., a second element), the element may be engaged with the other element directly or via a third element.

As used herein, the term “module” may include a unit implemented in hardware, software, or firmware, or any combination thereof, and may interchangeably be used with other terms, for example, logic, logic block, part, or circuitry. A module may be a single integral component, or a minimum unit or part thereof, adapted to perform one or more functions. For example, the module may be implemented in a form of an application-specific integrated circuit (ASIC).

Various embodiments as set forth herein may be implemented as software (e.g., a program) including one or more instructions that are stored in a storage medium (e.g., internal memory or external memory) that is readable by a machine (e.g., a computer). The machine may invoke at least one of the one or more instructions stored in the storage medium, and execute it. The machine may include an electronic device according to the disclosed embodiments. When the instruction is executed by a processor, the function corresponding to the instruction may be executed, using other components under the control of the processor. The one or more instructions may include a code made by a complier or a code executable by an interpreter. The machine-readable storage medium may be provided in the form of a non-transitory storage medium. Herein, the “non-transitory” storage medium is a tangible device, and may not include a signal, but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed online via an application store (e.g., PlayStore™). If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

While the disclosure has been illustrated and described with reference to various example embodiments, it will be understood that the various example embodiments are intended to be illustrative, not limiting. It will be further understood by one of ordinary skill in the art that various changes in form and detail may be made without departing from the true spirit and full scope of the disclosure, including the appended claims and their equivalents.

What is claimed is:

1. An electronic device comprising:
a first housing;
a second housing configured to detachably and rotatably engage with the first housing upon a first rotation axis, and defining an inner space when engaged with the first housing;
a first waveguide supported by the first housing and extending toward the second housing along the first rotation axis in the inner space;
a second waveguide supported by the second housing, extending toward the first housing along the first rotation axis in the inner space, and aligned to be spaced apart from the first waveguide by a predetermined distance;
a first coil disposed in the first housing and outside the first waveguide; and
a second coil disposed in the second housing, outside the second waveguide, and at a position corresponding to the first coil.

2. The electronic device of claim 1, wherein the first waveguide and the second waveguide are configured to transmit and/or receive a wireless communication signal, and the first coil and the second coil are configured to transmit and/or receive wireless power.

3. The electronic device of claim 1, wherein a recess or a protrusion is provided at one side of the first waveguide, opposing the second waveguide, or a recess or a protrusion is provided at one side of the second waveguide, opposing the first waveguide.

4. The electronic device of claim 1, further comprising:
a first ferrite core disposed in the first housing and surrounding at least a part of the first coil; and
a second ferrite core disposed in the second housing and surrounding at least a part of the second coil.

5. The electronic device of claim 1, wherein the second housing includes a driver including a drive motor and is electrically coupled to an external power source.

6. The electronic device of claim 1, wherein the second housing is configured to rotate upon the first rotation axis by a hollow motor.

7. The electronic device of claim 1, wherein a plurality of first coils are provided and configured to transmit power to a plurality of second coils corresponding to the first coils, respectively.

8. The electronic device of claim 7, further comprising a power management unit comprising power management circuitry,
wherein the power management unit is configured to determine a power-related parameter for power to be transmitted through each of the plurality of first coils.

9. The electronic device of claim 8, wherein the power-related parameter includes a voltage or a current of the power to be transmitted.

10. The electronic device of claim 1, wherein the distance between the first waveguide and the second waveguide is determined based on a frequency characteristic of a signal transmitted between the first waveguide and the second waveguide.

11. An electronic device configured to rotatably engage with an adjacent electronic device and including a first waveguide and a first coil disposed outside the first waveguide, the electronic device comprising:
a second waveguide aligned to be spaced apart from the first waveguide by a predetermined distance, based on the electronic device being engaged with the adjacent electronic device;
a second coil disposed outside the second waveguide and configured to be disposed at a position corresponding to the first coil based on the electronic device being engaged with the adjacent electronic device,; and
a motor configured to rotate the electronic device upon a rotation axis with respect to the adjacent electronic device.

12. The electronic device of claim 11, wherein the second waveguide is configured to transmit and/or receive a wireless communication signal to and from the first waveguide, and the second coil is configured to transmit and/or receive wireless power to and from the first coil.

13. The electronic device of claim 11, wherein a recess or a protrusion is provided at one side of the first waveguide, opposing the second waveguide, or a recess or a protrusion is provided at one side of the second waveguide, opposing the first waveguide.

14. The electronic device of claim 11, further comprising a ferrite core surrounding at least a part of the second coil.

15. A method of operating an electronic device, the method comprising:
detecting an external device in response to engagement with the external device;
transmitting first power to operate a processor of the external device through a first coil;
receiving information about the external device from the external device based on the operation of the processor of the external device;
determining a power-related parameter for power to be transmitted to the external device based on the information received from the external device;
transmitting second power through the first coil based on the determined power-related parameter; and
transmitting and receiving data to and/or from a second waveguide of the external device through a first waveguide.

16. The method of claim 15, wherein based on the electronic device being engaged with the external device, the first waveguide is aligned to be distanced from the second waveguide by a predetermined distance.

17. The method of claim 15, wherein the information about the external device includes at least one of an identifier (ID) of the external device, information about a type of the external device, information about required power for the external device, information about a voltage or a current related to charging power of the external device, or rating information about the external device.

18. The method of claim 15, wherein the detection of an external device comprises detecting the external device based on a change in a signal transmitted from the electronic device through the first coil.

19. The method of claim 15, wherein the detection of an external device comprises identifying whether the external device is engaged with the electronic device through a hall sensor disposed at a position near to the external device.

20. The method of claim 15, wherein the power-related parameter includes a voltage or a current of the power to be transmitted.
